(19) United States
(12) Patent Application Publication
(10) Pub. No.: US 2026/0190618 A1
(43) Pub. Date: Jul. 2, 2026

(54) LIGHT EMITTING DISPLAY DEVICE

(71) Applicant: LG Display Co., Ltd., Seoul (KR)

(72) Inventors: InGoo Lee, Gyeonggi-do (KR); SeHong Park, Gyeonggi-do (KR); Kyuhwan Lee, Gyeonggi-do (KR)

(21) Appl. No.: 19/430,578

(22) Filed: Dec. 23, 2025

(30) Foreign Application Priority Data
Dec. 31, 2024 (KR) 10-2024-0202066

(51) Int. Cl. H10K 50/856; H10K 59/124; H10K 59/80

(52) U.S. Cl. CPC H10K 50/856; H10K 59/124; H10K 59/878

(57) ABSTRACT

A light emitting display device includes a substrate, a plurality of pixels, a light emitting diode, a side mirror, a first internal mirror, and a second internal mirror. The plurality of pixels is arrayed on the substrate. Each of the pixels has an emission area and a non-emission area. The light emitting diode is disposed within the each pixel. The side mirror is disposed at an outer circumferences of the light emitting diode. The first internal mirror has an arc shape and is disposed inside the light emitting diode. The second internal mirror has the arc shape and is disposed inside the light emitting diode. One end point of the second internal mirror is located on an extension of a straight line connecting one end point of the first internal mirror to a center point of the light emitting diode.

### CROSS-REFERENCE TO RELATED APPLICATIONS

Pursuant to 35 U.S.C. § 119(a), this application claims the benefit of an earlier filing date and right of priority to Korean Patent Application No. 10-2024-0202066 filed on December 31, 2024, the contents of which are hereby incorporated by reference in their entirety.

### TECHNICAL FIELD

The present disclosure generally relates to a light emitting display device.

### BACKGROUND

Light emitting display devices are typically designed with a goal of achieving a wide viewing angle, excellent contrast, and fast response speed. The light emitting element used in a light emitting display device may have a light emitting layer made of organic or inorganic material arranged between an anode electrode and a cathode electrode.

In the light emitting element, holes are supplied from the anode electrode and electrons are supplied from the cathode electrode, and then the electrons and holes combine at the emission layer to generate excitons. As the excitons change from the excited state to the ground state, the fluorescent molecules in the emission layer may emit light to express color.

Some of the light emitted from the emission layer of the light emitting display device may not be emitted to the outside and may be lost due to total reflection within the electrode layer having a high refractive index, or due to total reflection occurring at the interface between the emission layer and the electrodes and/or the interface between the substrate and the air. This may result in a problem of reduced light extraction efficiency.

To overcome these problems and improve the light extraction efficiency of light emitting devices, microlenses or microcavity structures can be implemented inside the devices. However, although these structures improve the luminous efficiency of light emitted in the vertical direction of the display device, they cannot extract light emitted in the horizontal direction to the vertical direction. Therefore, existing methods have limitations in improving overall light extraction efficiency.

### SUMMARY

A light emitting display device according to some implementations of the present disclosure includes: a substrate, a plurality of pixels, a light emitting diode, a side mirror, a first internal mirror and a second internal mirror. The plurality of pixels is arrayed on the substrate. Each of the pixels has an emission area and a non-emission area. The light emitting diode is disposed within the each pixel. The side mirror is disposed at an outer circumference of the light emitting diode. The first internal mirror has an arc shape and is disposed inside the light emitting diode. The second internal mirror has the arc shape and is disposed inside the light emitting diode. One end point of the second internal mirror is located on an extension of a straight line connecting one end point of the first internal mirror to a center point of the light emitting diode.

Such features can provide various technical improvements. For example, the light emitting display device may have a structure in which almost all of the lights emitted from the emission layer may be extracted to the outside without being trapped and extinguished inside of the device, thereby providing a bottom emission type light emitting display device with maximized light extraction efficiency.

As another example, the light emitting display device may provide a bottom emission type light emitting display device that minimizes non-emission areas and improve light extraction efficiency by arranging micro mirrors (or reflectors) without using a bank covering the circumferences of the pixel electrode.

As another example, with the micro-mirror structure formed at the edge of the anode electrode, the light emitting display device may further extract lights that would otherwise be lost within the light emitting diode (or, within the anode electrode). In particular, by implementing a structure in which lights that may be lost within the light emitting diode (or, within the anode electrode) in the central portion of the pixel may be also extracted to the outside, the light extraction efficiency may be further improved.

In addition, lights which otherwise may be extinguished by the total reflection between the planarization layer (or the layer disposed underneath) and the substrate. For example, in a plan view, lights which otherwise may be trapped and extinguished inside the light emitting diode may be extracted to the bottom of the substrate by breaking the total reflection condition by the internal mirror having an arc shape. Therefore, the light emitting display device according to the present disclosure may enhance the light extraction efficiency. Accordingly, the light emitting display device may provide higher brightness with the same power consumption, or may use lower power consumption to provide the same brightness. Therefore, the light emitting display device according to the present disclosure may be driven at low power consumption.

The effects that may be obtained from the present disclosure are not limited to the effects mentioned above, and other effects that are not mentioned may be clearly understood by those skilled in the art to which this disclosure belongs from the description above.

### BRIEF DESCRIPTION OF THE DRAWINGS

The accompanying drawings, which are included to provide a further understanding of the disclosure and are incorporated in and constitute a part of this application, illustrate implementations of the disclosure and together with the description serve to explain the principle of the disclosure. In the drawings:

FIG. 1 is a diagram illustrating an example of a schematic structure of a light emitting display device according to the present disclosure.

FIG. 2 is a circuit diagram illustrating a structure of one pixel included in the light emitting display device according to an example of the present disclosure.

FIG. 3 is a plan view illustrating an arrangement structure of the pixels arrayed in one unit-pixel of the light emitting display device according to an example of the present disclosure.

FIG. 4 is an enlarged cross-sectional view, taken along line I-I’ in FIG. 3, for illustrating the structure of a light emitting display device according to an example of the present disclosure.

FIG. 5 is an enlarged cross-sectional view, taken along line II-II’ in FIG. 3, for illustrating light paths in a light emitting display device according to an example of the present disclosure.

FIG. 6 is an enlarged cross-sectional view, taken along line II-II’ of FIG. 3, illustrating an example of a structure of a light emitting display device according to a first implementation of the present disclosure.

FIG. 7 is a schematic diagram illustrating an example of representative optical paths of the lights reflected by the side mirror in the light emitting display device according to a first implementation of the present disclosure.

FIG. 8 is an enlarged cross-sectional view illustrating an example of optical paths of the lights trapped and extinguished inside the pixel on the plan view of the light emitting display device according to a first implementation of the present disclosure.

FIG. 9 is a plan view illustrating an example of a structure of one pixel in a light emitting display device according to a second implementation of the present disclosure.

FIGS. 10A and 10B are diagrams for illustrating an example of optical paths of the lights not trapped and emitted out from the pixel on the plan view of the light emitting display device according to a second implementation of the present disclosure.

FIG. 11 is an enlarged cross-sectional view, taken along line III-III’ of FIG. 9, illustrating an example of a structure of a light emitting display device according to a second implementation of the present disclosure.

FIG. 12 is an enlarged plan view illustrating an example of a structure of one pixel in a light emitting display device according to a third implementation of the present disclosure.

FIG. 13 is an enlarged plan view illustrating an example of a structure of one pixel in a light emitting display device according to a fourth implementation of the present disclosure.

FIG. 14 is an enlarged plan view illustrating an example of a structure of one pixel in a light emitting display device according to a fifth implementation of the present disclosure.

FIG. 15 is an enlarged plan view illustrating an example of a structure of one pixel in a light emitting display device according to a sixth implementation of the present disclosure.

FIG. 16 is an enlarged plan view illustrating an example of a structure of one pixel in a light emitting display device according to a seventh implementation of the present disclosure.

### DETAILED DESCRIPTION

Implementations of the present disclosure can provide a bottom emission type light emitting display device having micro mirrors to enhance the light extraction efficiency.

Implementations of the present disclosure can provide a bottom emission type light emitting display device that improves light extraction efficiency by extracting light generated from the emission layer to the outside, which would otherwise be trapped inside the device and disappear due to total reflection.

Implementations of the present disclosure can provide a bottom emission type light emitting display device that improves brightness (or luminance) degradation rate and light extraction efficiency by arranging a micro mirror structure on the edge of the light emitting area to maximize the area of the light emitting area. In particular, implementations of the present disclosure can provide a bottom emission type light emitting display device that improves light extraction efficiency and enhances brightness per power consumption by extracting light to the outside, which may otherwise be extinguished by an electric field from the central portion of the anode electrode.

Advantages and features of the present disclosure, and implementation methods thereof will be clarified through following implementations described with reference to the accompanying drawings. The present disclosure may, however, be embodied in different forms and should not be construed as limited to the implementations set forth herein. Rather, these example implementations are provided so that this disclosure may be sufficiently thorough and complete to assist those skilled in the art to fully understand the scope of the present disclosure. Further, the protected scope of the present disclosure is defined by claims and their equivalents.

The shapes, sizes, ratios, angles, numbers, and the like, which are illustrated in the drawings in order to describe various example implementations of the present disclosure, are merely given by way of example. Therefore, the present disclosure is not limited to the illustrated details. Like reference numerals refer to like elements throughout the specification unless otherwise specified. In the following description, where the detailed description of the relevant known function or configuration may unnecessarily obscure an important point of the present disclosure, a detailed description of such known function of configuration may be omitted.

Reference will now be made in detail to the exemplary implementations of the present disclosure, examples of which are illustrated in the accompanying drawings. Wherever possible, the same reference numbers will be used throughout the drawings to refer to the same or like parts. In the specification, it should be noted that like reference numerals already used to denote like elements in other drawings are used for elements wherever possible. In the following description, when a function and a configuration known to those skilled in the art are irrelevant to the essential configuration of the present disclosure, their detailed descriptions will be omitted. The terms described in the specification should be understood as follows.

In the present specification, where the terms “comprise,” “have,” “include,” and the like are used, one or more other elements may be added unless the term, such as “only,” is used. An element described in the singular form is intended to include a plurality of elements, and vice versa, unless the context clearly indicates otherwise.

In construing an element, the element is construed as including an error or tolerance range even where no explicit description of such an error or tolerance range is provided.

In the description of the various implementations of the present disclosure, where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third layer or element may be interposed therebetween. Also, if a first element is described as positioned “on” a second element, it does not necessarily mean that the first element is positioned above the second element in the figure. The upper part and the lower part of an object concerned may be changed depending on the orientation of the object. Consequently, where a first element is described as positioned “on” a second element, the first element may be positioned “below” the second element or “above” the second element in the figure or in an actual configuration, depending on the orientation of the object.

In describing a temporal relationship, when the temporal order is described as, for example, “after,” “subsequent,” “next,” or “before,” a case which is not continuous may be included unless a more limiting term, such as “just,” “immediate(ly),” or “direct(ly),” is used.

It will be understood that, although the terms “first,” “second,” and the like may be used herein to describe various elements, these elements should not be limited by these terms as they are not used to define a particular order. These terms are used only to distinguish one element from another. For example, a first element could be termed a second element, and, similarly, a second element could be termed a first element, without departing from the scope of the present disclosure.

In describing various elements in the present disclosure, terms such as first, second, A, B, (a), and (b) may be used. These terms are used merely to distinguish one element from another, and not to define a particular nature, order, sequence, or number of the elements. Where an element is described as being “linked”, “coupled,” or “connected” to another element, that element may be directly or indirectly connected to that other element unless otherwise specified. It is to be understood that additional element or elements may be “interposed” between the two elements that are described as “linked,” “connected,” or “coupled” to each other.

To elaborate, as used herein, the term "connected" is intended to have the broadest possible meaning. Specifically, the phrase "A is connected to B" encompasses both a direct connection—where no intervening components or elements are present—and an indirect connection, where one or more intermediate components or elements exist between A and B. In other words, "A is connected to B" includes both direct physical or electrical coupling and indirect coupling through one or more intervening components. Unless explicitly stated otherwise, these terms do not require direct physical or electrical contact. The term "coupled" and "in contact" should be interpreted in the same manner.

It should be understood that the term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

Features of various implementations of the present disclosure may be partially or overall coupled to or combined with each other, and may be variously inter-operated with each other and driven technically as those skilled in the art can sufficiently understand. The implementations of the present disclosure may be carried out independently from each other, or may be carried out together in a co-dependent relationship.

Hereinafter, an example of a display apparatus according to the present disclosure will be described in detail with reference to the attached drawings. Wherever possible, the same reference numbers will be used throughout the drawings to refer to the same or like parts.

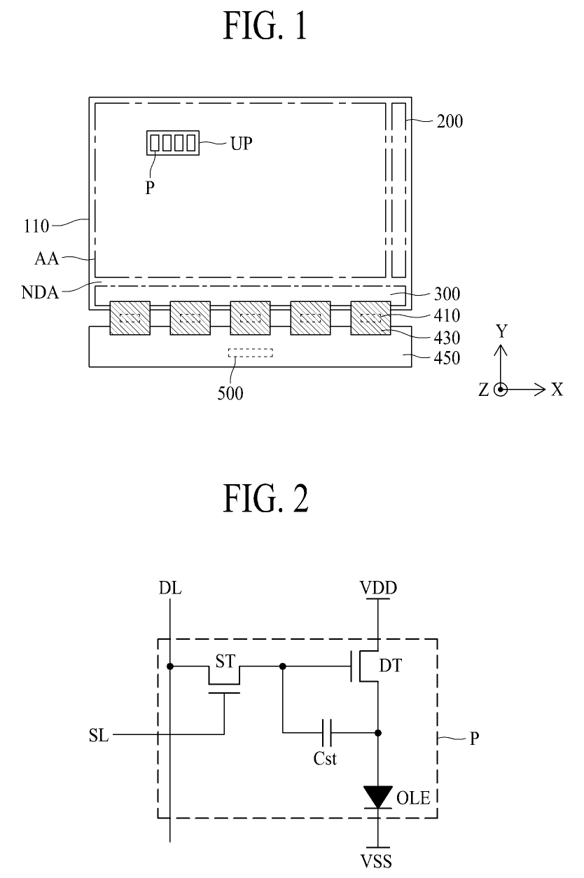

Hereinafter, referring to figures, various implementations of the present disclosure will be explained. FIG. 1 is a diagram illustrating an example of a schematic structure of a light emitting display device according to the present disclosure. In FIG. 1, the X-axis refers to the direction parallel to the scan line, the Y-axis refers to the direction of the data line, and the Z-axis refers to the height (or, thickness) direction of the display device.

Referring to FIG. 1, the light emitting display device includes a substrate 110, a gate (or scan) driver 200, a pad portion 300, a source driving IC (Integrated Circuit) 410, a flexible circuit film 430, a circuit board 450, and a timing controller 500.

The substrate 110 may include an electrical insulating material or a flexible material. The substrate 110 may be made of a glass, a metal or a plastic, but it is not limited thereto. When the light emitting display device is a flexible display, the substrate 110 may be made of the flexible material such as plastic. For example, the substrate 110 may include a transparent polyimide material.

The substrate 110 may include a display area AA and a non-display area NDA. The display area AA, which is an area for representing the video images, may be defined as the majority middle area of the substrate 110, but it is not limited thereto. In the display area AA, a plurality of scan lines (or gate lines), a plurality of data lines and a plurality of unit pixels UP may be formed or disposed. The unit pixels UP are arrayed in a matrix manner. Each of unit pixels UP may include a plurality of pixels P. Each of pixels P includes the scan line and the data line, respectively.

The non-display area NDA, which is an area not representing the video images, may be defined at the circumference areas of the substrate 110 surrounding all or some of the display area AA. In the non-display area NDA, the gate driver 200 and the pad portion 300 may be formed or disposed.

The gate driver 200 may supply the scan (or gate) signals to the scan lines according to the gate control signal input through the pad portion 300 from the timing controller 500. The gate driver 200 may be formed at the non-display area NDA at any one outside of the display area AA on the substrate 110, as a GIP (Gate driver In Panel) type. GIP type means that the gate driver 200 is directly formed on the substrate 110. For example, the gate driver 200 may be configured as a shift resistor, and the GIP type refers to a structure in which transistors for the shift resistor of the gate driver 200 are directly formed on the substrate 110.

The pad portion 300 may supply data signals to data lines according to a data control signal input from the timing controller 500. The pad portion 300 may be formed as a driving chip and mounted the flexible circuit film 430. The flexible circuit film 430 may be attached to the non-display area NDA of one edge of the display area AA of the substrate 110.

The source driving IC 410 may receive the digital video data and the source control signal from the timing controller 500. The source driving IC 410 may convert the digital video data into the analog data voltages according to the source control signal and then supply that to the data lines. When the source driving IC 410 is made as a chip type, it may be installed on the flexible circuit film 430 as a COF (chip on film) or COP (chip on plastic) type.

The flexible circuit film 430 may include a plurality of first link lines connecting the pad portion 300 to the source driving IC 410, and a plurality of second link lines connecting the pad portion 300 to the circuit board 450. The flexible circuit film 430 may be attached on the pad portion 300 using an anisotropic conducting film, so that the pad portion 300 may be connected to the first link lines of the flexible circuit film 430.

The circuit board 450 may be attached to the flexible circuit film 430. The circuit board 450 may include a plurality of circuits implemented as the driving chips. For example, the circuit board 450 may be a printed circuit board or a flexible printed circuit board. The circuit board 450 may be a printed circuit board or a flexible printed circuit board.

The timing controller 500 may receive the digital video data and the timing signal from an external system board through the line cables of the circuit board 450. The timing controller 500 may generate a gate control signal for controlling the operation timing of the gate driver 200 and a source control signal for controlling the source driving IC 410, based on the timing signal. The timing controller 500 may supply the gate control signal to the gate driver 200 and supply the source control signal to the source driving IC 410. Depending on the product types, the timing controller 500 may be formed as one chip with the source driving IC 410 and mounted on the substrate 110.

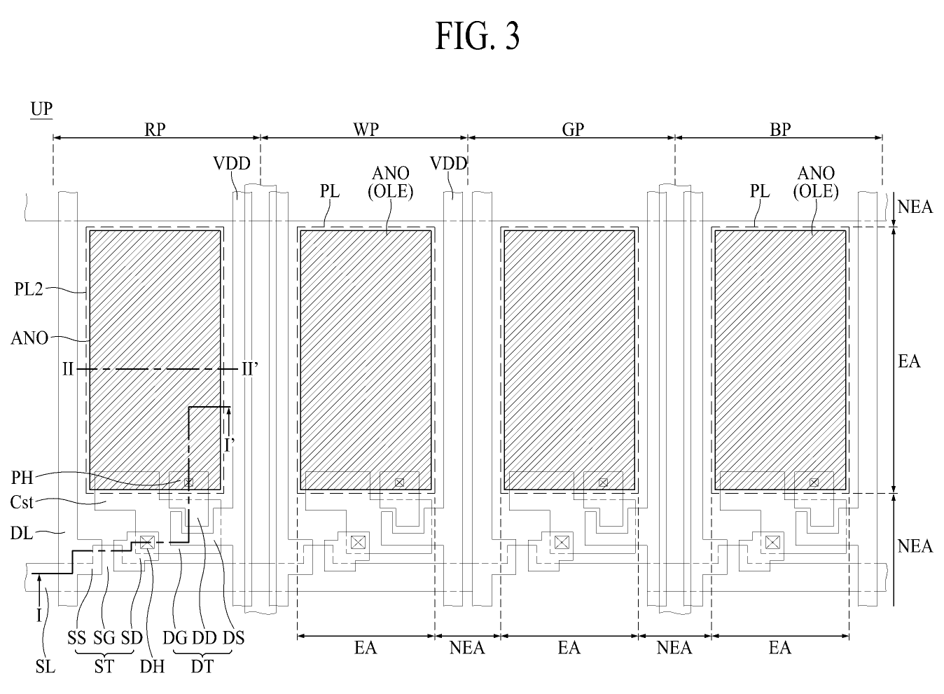

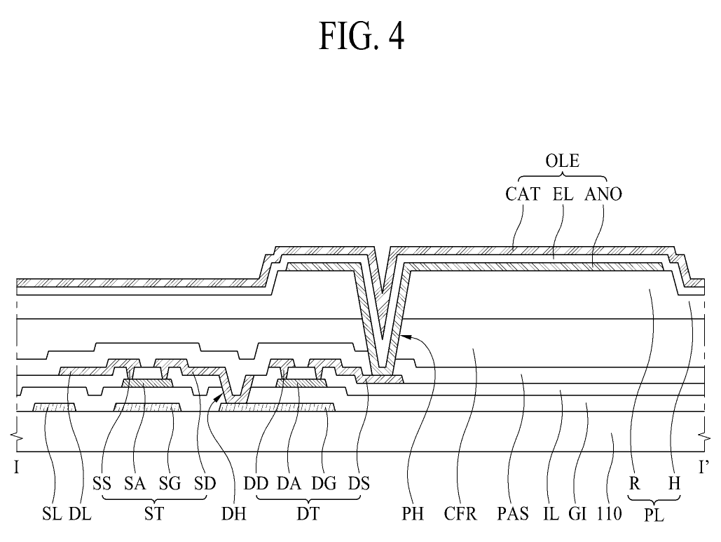

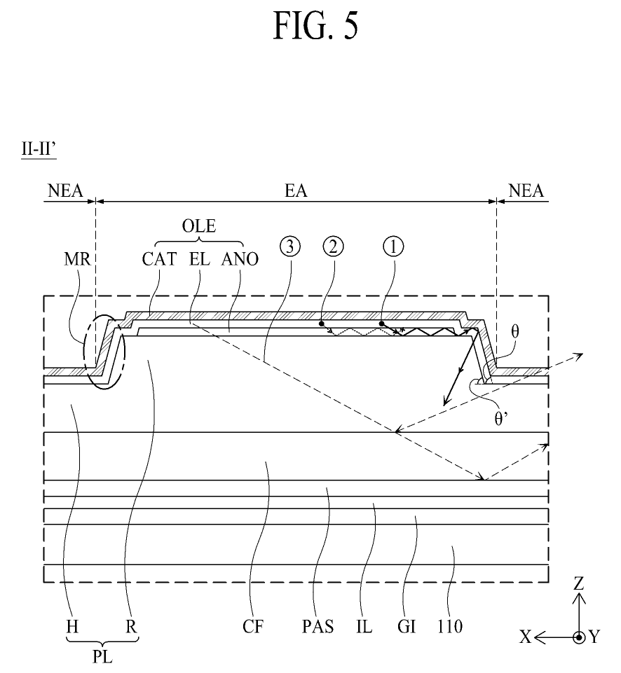

Hereinafter, referring to FIGS. 2 to 4, an implementation of the present disclosure will be explained. FIG. 2 is a circuit diagram illustrating a structure of one pixel included in the light emitting display device according to an example of the present disclosure. FIG. 3 is a plan view illustrating an arrangement structure of the pixels arrayed in a unit-pixel of the light emitting display device according to an example of the present disclosure. FIG. 4 is an enlarged cross-sectional view along to cutting line I-I’ in FIG. 3, for illustrating the structure of a light emitting display device according to an example of the present disclosure.

Referring to FIGS. 2 to 4, a light emitting display device includes a plurality of unit pixels P in a matrix arrangement. Each unit pixel UP of the light emitting display may include three pixels P or four pixels P. For example, one unit pixel P may include a red pixel RP, a green pixel GP and a blue pixel BP. For another example, as shown in FIG. 3, one unit pixel UP may include one red pixel RP, a white pixel WP, a green pixel GP, and a blue pixel BP.

One pixel P of the light emitting display device, i.e., any one among red pixel RP, white pixel WP, green pixel GP and blue pixel BP, may be defined by a scan line SL, a data line DL and a driving current line VDD. A pixel P may include an emission area EA and a non-emission area NEA. The emission area EA may be an area providing light emissions for representing video and/or picture image. The non-emission area NEA may be an area not providing any light emissions. In any one pixel of the light emitting display device may include a switching thin film transistor ST, a driving thin film transistor DT, a light emitting diode OLE, and a capacitance Cst. The driving current line VDD may be supplied with a high-level voltage for driving the light emitting diode OLE.

For example, the switching thin film transistor ST may be disposed at a location where the scan line SL and the data line DL intersect. The switching thin film transistor ST may include a gate electrode SG, a semiconductor layer SA, a source electrode SS and a drain electrode SD. The gate electrode SG may be connected to the scan line SL. The source electrode SS may be connected to the data line DL, and the drain electrode SD may be connected to the driving thin film transistor DT. The semiconductor layer SA may be disposed on a gate insulating layer GI as overlapping with the gate electrode SG. The portion of the semiconductor layer SA overlapping the gate electrode SG may be defined as a channel region.

An intermediate insulating layer IL may be deposited on the semiconductor layer SA. The source electrode SS and the drain electrode SD may be formed on the intermediate insulating layer IL. The source electrode SS may be connected to one side of the semiconductor layer SA via one contact hole formed at the intermediate insulating layer IL. The drain electrode SD may be connected to another side of the semiconductor layer SA via another contact hole formed at the intermediate insulating layer IL. The switching thin film transistor ST may select a pixel P to be driven by applying a data signal to the driving thin film transistor DT.

The driving thin film transistor DT may drive the light emitting diode OLE of the pixel selected by the switching thin film transistor ST. The driving thin film transistor DT may include a gate electrode DG, a semiconductor layer DA, a source electrode DS and a drain electrode DD. The gate electrode DG of the driving thin film transistor DT may be connected to the drain electrode SD of the switching thin film transistor ST. For example, the gate electrode DG of the driving thin film transistor DT may be connected to the drain electrode SD of the switching thin film transistor ST via a drain contact hole DH penetrating the gate insulating layer GI covering the gate electrode DG. The drain electrode DD may be connected to the driving current line VDD, and the source electrode DS may be connected to an anode electrode ANO of the light emitting diode OLE. The capacitance Cst may be disposed between the gate electrode DG of the driving thin film transistor DT and the anode electrode ANO of the light emitting diode OLE.

The intermediate insulating layer IL may be deposited on the semiconductor layer DA. The source electrode DS and the drain electrode DD may be formed on the intermediate insulating layer IL. The source electrode DS may be connected to one side of the semiconductor layer DA via one contact hole formed at the intermediate insulating layer IL. The drain electrode DD may be connected to another side of the semiconductor layer DA via another contact hole formed at the intermediate insulating layer IL.

The driving thin film transistor DT may be disposed between the driving current line VDD and the light emitting diode OLE. The driving thin film transistor DT may control the amount of current flowing from the driving current line VDD to the light emitting diode OLE according to the magnitude of the voltage of the gate electrode DG connected to the drain electrode SD of the switching thin film transistor ST.

The light emitting diode OLE may include an anode electrode ANO, an emission layer EL and a cathode electrode CAT. The light emitting diode OLE may emit lights in response to an electric current controlled by the driving thin film transistor DT. In detail, since the amount of light emitted may be adjusted according to the current controlled by the driving thin film transistor DT, the brightness of the light emitting display device may be controlled. The anode electrode ANO of the light emitting diode OLE may be connected to the source electrode DS of the driving thin film transistor DT, and the cathode electrode CAT may be connected to a low voltage line VSS to which a low potential voltage is applied. The light emitting diode OLE may be driven by the difference between a low-potential voltage and a high-potential voltage controlled by a driving thin film transistor DT.

A passivation layer PAS is deposited on the surface of the substrate 110 having the thin film transistors ST and DT. The passivation layer PAS may include an inorganic material such as silicon oxide (SiOx) or silicon nitride (SiNx). The thin layers configuring the thin film transistors ST and DT formed on the substrate 110 may be called as a ‘driving element layer.’ For example, from a metal layer of the scan line SL and the gate electrodes SG and DG to the passivation layer PAS covering the thin film transistors ST and DT may be defined as the driving element layer.

A color filter CF may be formed on the passivation layer PAS. The color filter CF may be disposed on each pixel P. For example, the color filter may include a red color filter CFR disposed at the red pixel RP, a green color filter CFG disposed at the green pixel GP, and a blue color filter CFB disposed at the blue pixel BP. Color filter may not be disposed at the white pixel WP.

A planarization layer PL may be deposited on the color filter CF. The planarization layer PL may be a thin film for making the surface of the substrate 110 on which thin film transistors ST and DT are formed flat. To make even the height difference, the planarization layer PL may be formed of an organic material.

A pixel contact hole PH for exposing a portion of the source electrode DS of the driving thin film transistor DT may be formed as penetrating the passivation layer PAS, the color filter CF and the planarization layer PL. An anode electrode ANO may be formed on the planarization layer PL. The anode electrode ANO may be connected to the source electrode DS of the driving thin film transistor DT via the pixel contact hole PH.

The planarization layer PL may have a level difference. For example, the planarization layer PL may be patterned using an anode electrode ANO as a mask. As a result, the planarization layer PL may have a structure in which portions of the planarization layer PL may protrude upward, and the anode electrode ANO is formed on the protruded portions of the planarization layer PL.

The anode electrode ANO may have different material depending on the emission type of the light emitting diode OLE. For the bottom emission type in which the light emitting diode OLE emits toward the substrate 110, the anode electrode ANO may be formed of a transparent conductive material. For the top emission type in which the light emitting diode OLE emits upward opposing the substrate 110, the anode electrode ANO may be formed of a metal material having excellent light reflectance. In this case, the anode electrode ANO may have a structure in which a transparent conductive layer and a metal layer are stacked.

For the bottom emission type, the anode electrode ANO may be made of a transparent conductive material (TCO) or semi-transparent conductive material. For instance, the anode electrode ANO may be made of a transparent conductive material such as indium tin oxide (ITO), indium zinc oxide (IZO) or indium zinc tin oxide (IZTO). Otherwise, the anode electrode ANO may be made of a semi-transparent layer of magnesium (Mg), silver (Ag) or an alloy of magnesium (Mg) and silver (Ag) with a thickness of less than 100nm. The anode electrode ANO may be called as a first electrode or a transparent electrode.

An emission layer EL may be deposited on the anode electrode ANO. In some implementations, the emission layer EL may be disposed on the entire surface of the substrate 110 as one sheet type covering continuously the upper surface of the substrate 110. The emission layer EL may include various functional layers stacked each other. For example, the emission layer EL may include a hole functional layer, an organic emission layer, an electron functional layer. Each of the hole functional layer and the electron functional layer may be deposited on the substrate 110 as continuous sheet type. The organic emission layer may have a sheet shape between the hole functional layer and the electron functional layer. However, it is not limited thereto. The organic emission layer may be disposed as separated as corresponding to each emission area EA of each pixel P.

In addition, the emission layer EL may include two or more emission portions for emitting white color light. For example, the emission layer EL may have a tandem structure in which a first emission layer and a second emission layer are vertically stacked for emitting white color light by mixing a first color light and a second color light. However, it is not limited thereto, the vertically stacked emission portions may include three or four layers.

A cathode electrode CAT may deposited on the emission layer EL. The cathode electrode CAT may be disposed as a thin layer shape continuously spread on the entire surface of the substrate 110. The stacked structure of the anode electrode ANO, the emission layer EL and the cathode electrode CAT may configure the light emitting diode OLE.

The cathode electrode CAT may be made of a metal material having excellent light reflectance. For example, the cathode electrode CAT may be formed of a metal material with excellent light reflectance with a thickness of at least 2,000Å to 3,000Å (200nm to 300nm). For example, the metal material having excellent light reflectance may include aluminum (Al), magnesium (Mg), calcium (Ca), silver (Ag) or alloy of them (i.e., aluminum-magnesium alloy (AlMg)) For another example, the cathode electrode CAT may include thin metal layer having high reflectance such as stack of aluminum and titanium (Ti/Al/Ti), stack of aluminum and indium tin oxide (ITO/Al/ITO), silver alloy, or stack of silver alloy and indium tin oxide (ITO/Ag alloy/ITO). Here, silver alloy may be an alloy of silver (Ag), palladium (Pd) and copper (Cu). The cathode electrode CAT may be referred to as a second electrode, reflection electrode, or counter electrode.

The stacked structure of the anode electrode ANO, the emission layer EL and the cathode electrode CAT may configure the light emitting diode OLE. The light emitting display device according to some implementations the present disclosure may have a structure in which each of light emitting diode OLE is disposed on the planarization layer PL patterned with protruding island shape within the pixel P. The elements from the planarization layer PL deposited on the driving element layer to the cathode electrode CAT of the light emitting diode OLE may be collectively referred to as a ‘light emitting element layer.’

As a detailed example, within each pixel P, a planarization layer PL is applied over the entire surface of the substrate 110, and has a protruding portion in the shape of an island with a certain thickness. The anode electrode ANO is formed on the upper surface of the protruding portion of the planarization layer PL. The emission layer EL may be deposited to cover the upper surface of the planarization layer PL (which has steps) and the upper surface of the anode electrode ANO. The cathode electrode CAT may be also deposited with the same profile as the emission layer EL. As a result, the cathode electrode CAT may have a cap, ‘∩’, shape facing downward. Since the cathode electrode CAT may be made of a metal material with excellent light reflectance, the cathode electrode CAT may have a structure that forms cap shaped micro mirrors along the protruding portion of the planarization layer PL.

In the case of the bottom emission type, there may be a disadvantage in that the area ratio of the aperture area to the pixel area may be relatively smaller than a top emission type, due to the thin film transistor ST and DT, capacitance Cst, the scan line SL, the data line DL and the driving current line VDD. The light emitting display device according to some implementations the present disclosure may provide a structure equipped with a micro mirror MR so that light generated from the emission layer may be provided toward the substrate 110 placed underneath without loss even though the aperture area is small.

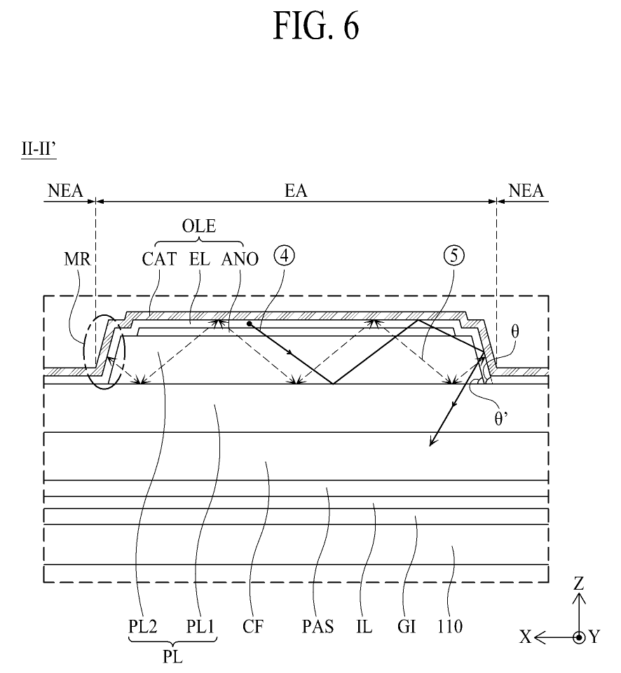

Hereinafter, referring to FIG. 5, an example of the mechanism for enhancing the light extraction efficiency by the micro mirror MR will be explained. FIG. 5 is an enlarged cross-sectional view along to cutting line II-II’ in FIG. 3, for illustrating light paths in a light emitting display device according to an example of the present disclosure.

Referring to FIG. 5, a description is provided of the optical path ① for light emitted from the emission layer EL at the edge region of the anode electrode ANO. Lights emitted from the emission layer EL may be transmitted(or, propagated) as a spherical wave. Lights may be emitted in all directions (360 degrees) from the cross-sectional view. Among the lights, the light emitted to the top direction may be reflected by the cathode electrode CAT and travel downward. That is, most of all lights generated from the emission layer EL may be radiated in a 180-degree range in a downward direction. These lights may be incident into the anode electrode ANO. Since the anode electrode ANO is made of a transparent conductive material, a portion such as 60% to 70% of the lights may pass through the anode electrode ANO, then pass through the color filter CF placed underneath, and then be emitted outside the substrate 110.

In some implementations, the anode electrode ANO may be a transparent conductive material with a refractive index of 2.0 to 2.3. The upper surface of the anode electrode ANO is in contact with the emission layer EL, and the bottom surface is in contact with the planarization layer PL. In some implementations, the emission layer EL and the planarization layer PL may have a refractive index of 1.3 to 1.5. As a result, a structure may be formed in which an anode electrode ANO with a high refractive index is interposed between two low refractive layers. Therefore, among the lights incident into the anode electrode ANO, a portion such as 30% to 40% of the lights corresponding to the total reflection condition may be propagated in the horizontal direction (X-axis direction) inside the anode electrode ANO.

According to the material of the emission layer EL, the refractive index of the emission layer EL may be similar to the refractive index of the anode electrode ANO. In this case, among the lights emitted from the emission layer EL, the lights totally reflected at the interface between the anode electrode ANO and the planarization layer PL may be trapped between the cathode electrode CAT and the planarization layer PL, so these lights may propagate in the horizontal direction (X-axis direction).

Lights propagating horizontally within the anode electrode ANO, or between the cathode electrode CAT and the planarization layer PL may be emitted from the end of the anode electrode ANO and be reflected by the cathode electrode CAT having the micro mirror MR to go downward. When there is no micro mirror structure formed by the protrusion of the planarization layer PL, the lights may be propagated horizontally and extinguished. However, according to the structure of some implementations disclosed herein, the lights can be extracted downward by the micro mirror formed by the cathode electrode CAT, thereby improving the light extraction efficiency.

The above description explained that light propagating in the horizontal direction may propagate while repeating the total reflection process inside the anode electrode ANO. However, implementations are not limited thereto. The lights propagating in the horizontal direction may propagate while repeating the total reflection process inside the element including the anode electrode ANO and emission layer EL, i.e., between the cathode electrode CAT and the planarization layer PL. For convenience, in this disclosure, description is provided for scenarios where the light is totally reflected inside the light emitting diode OLE and propagates in the horizontal direction.

In some implementations, in order to ensure that the lights reflected by the cathode electrode CAT having a micro mirror MR may be emitted to the downward direction properly, it can be necessary to adjust the angle of the inclination of the cathode electrode CAT deposited on the etched side where the step of the planarization layer PL is formed. For example, the angle θ of the inclined surface of the cathode electrode CAT with respect to the horizontal surface of the substrate 110 may be in the range of 50 degree to 80 degree. Since the cathode electrode CAT is deposited along the step shape of the planarization layer PL, the inclination angle θ of the cathode electrode CAT may be substantially equal to the side wall inclination angle θ’ of the protrusion R in the planarization layer PL. Therefore, in some implementations, the inclination angle θ’ is formed between the flat portion H and the protrusion portion R of the planarization layer PL to be 50 degrees to 80 degrees.

The light emitting display device according to some implementations of the present disclosure may include the cathode electrode CAT having the micro mirror MR according to the shape of the planarization layer PL having a protrusion portion R extruded as an island from the flat portion H. Therefore, the light extraction efficiency may be improved by extracting the light that may otherwise be extinguished inside the light emitting diode OLE among the lights generated from the emission layer EL.

Here, for convenience of explanation, description is provided based on one pixel, in which the planarization layer PL is described as a structure in which a protrusion portion R protrudes from the flat portion H. However, in some implementations, a large number of pixels can be arranged in a matrix manner, in which case the planarization layer PL can have a structure in which multiple protrusion portions R and multiple depression portions (corresponding to multiple flat portions H) are repeatedly arranged. That is, the flat portion H may be called a depression portion. In this case, the protrusion portions R may correspond to the emission areas within each pixel, and the depressed portions (flat portions H) may correspond to the non-emission areas surrounding the emission areas.

In FIG. 5, the region (or area) where the light emitting diode OLE is formed may generate lights. In addition, the region where the lights may be emitted to downward of the substrate 110 by the micro mirror MR may have slightly larger area than the light emitting diode OLE. In FIG. 5, the region including the micro mirror MR and the light emitting diode OLE may be defined as the emission area EA. The area except the emission area EA may be defined as the non-emission area NEA.

The light emitting display having the micro mirror MR described above may extract the lights that would otherwise be trapped and extinguished within the light emitting diode OLE to the outside of the light emitting diode OLE. However, the lights emitted from the emission layer EL at the central region of the light emitting diode OLE, in the plan view, may not be extracted to the outside.

Hereinafter, description is provided of the optical path ② for light emitted from the emission layer EL at the central region of the light emitting diode OLE on the plan view. Lights generated from the emission layer EL may be radiated in a 180 degree range downward by the same mechanism as described above. Since the anode electrode ANO is made of a transparent conductive material, a portion such as 60% to 70% of the lights may pass through the anode electrode ANO, then pass through the color filter CF placed underneath, and then be emitted outside the substrate 110.

However, among the lights incident into the anode electrode ANO, a portion such as 30% to 40% of the lights that meet the total reflection condition may be propagated in the horizontal direction (X-axis direction) inside the light emitting diode OLE. In particular, the lights generated at the central region of the pixel may undergo a total reflection process inside the light emitting diode OLE, so that the length of the propagating optical path ② may be much longer than the length of the optical path ① described above. Therefore, light traveling along the propagating optical path ② may be dissipated as heat energy inside the light emitting diode OLE before being emitted through the end of the light emitting diode OLE. In general, when lights propagate over a length of 20 µm or more inside the light emitting diode OLE, the lights may be extinguished or annihilated.

In addition, among the lights emitted from the light emitting diode OLE, even though these lights are incident into the planarization layer PL, there may be lights which are totally reflected from the lower surface of the planarization layer PL. Further, even though the lights may pass through the planarization layer PL, some of the lights may be totally reflected at the interface of the thin layers deposited underneath, for example, at the bottom of the color filter CF. Furthermore, even though these lights may pass through the color filter CF and the thin layers deposited thereunder, some lights may be totally reflected on the bottom surface of the substrate 110. The lights totally reflected at the interface of the thin layers deposited on the substrate 110, as shown by the optical path ③ of FIG. 5, may be not emitted from the emission area of the corresponding pixel and may be the lost lights.

Hereinafter, various implementations are described of the light emitting display device according to the present disclosure which may extract lights emitted from a light emitting diode OLE to the outside without being dissipated as heat energy or without being lost due to total reflection.

In the following explanation, descriptions for the driving element layer which are common to different figures will not be duplicated. Further, the configuration of the driving element layer is not limited to the examples of FIGS. 2 to 4. The configuration of the thin film transistors ST and DT may have any one structure of top gate structure, bottom gate structure and double gate structure. The thin film transistors ST and DT may include oxide semiconductor material. For example, the material for the semiconductor layers SA and DA may include a metal oxide material such as indium gallium zinc oxide (IGZO). However, it is not limited thereto, and the semiconductor layers SA and DA may include any one of an amorphous silicon (a-Si), a polycrystalline silicon (Poly Si), or a low temperature polycrystalline silicon (LTPS).

In addition, the arrangement of the signal lines including scan line SL, data line DL and driving current line VDD may be varied. Other signal lines including reference line may be further included. In the following description, drawing numeric symbols which are shown in the drawings but not explained may be referred to the description of the drawing numeric symbols in FIGS. 2 to 4.

### First Implementation

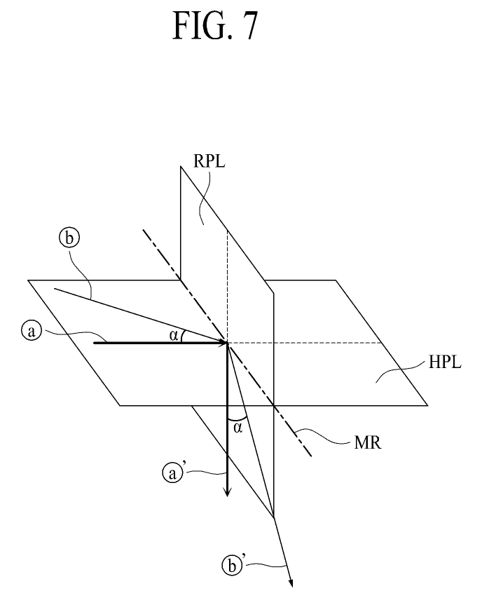

Hereinafter, referring to the example of FIG. 6 description will be provided of a structure of a light emitting display device according to a first implementation of the present disclosure. FIG. 6 is an enlarged cross-sectional view, taken along line II-II’ of FIG. 3, illustrating an example of a structure of a light emitting display device according to a first implementation of the present disclosure.

Referring to FIG. 6, a pixel P may include an emission area EA and a non-emission area NEA. In FIG. 6, the emission area EA may include the micro-mirror MR and the light emitting diode OLE. The area outside the emission area EA may be the non-emission area NEA.

Referring to FIG. 6, a gate insulating layer GI, an intermediate insulating layer IL and a passivation layer PAS may be sequentially stacked on a substrate 110. A color filter CF may be disposed on the passivation layer PAS. A planarization layer PL may be disposed on the color filter CF. The planarization layer PL may include a first planarization layer PL1 and a second planarization layer PL2 sequentially stacked. The first planarization layer PL1 may be deposited on the color filter CF as covering entire surface of the substrate 110 with a predetermined thickness. The second planarization layer PL2 may be formed as an island shape only at a location corresponding to the emission area where the anode electrode ANO is disposed within a pixel P. That is, the second planarization layer PL2 may have an island shape protruding or extracting on the first planarization layer PL1.

In some implementations, the sidewall inclined angle θ’ of the second planarization layer PL2 having a protruded shape (or island shape) on the first planarization layer PL1 may be the same as the sidewall inclined angle θ’ described with FIG. 5. Similarly, the inclined angle θ of the cathode electrode CAT deposited on the first planarization layer PL1 and the second planarization layer PL2 may be substantially the same as the sidewall inclined angle θ’ of the second planarization layer PL2 described with FIG. 6.

The first implementation may have a feature in which the second planarization layer PL2, which is in contact with the anode electrode ANO may include a transparent organic material having refractive index that is the same as or at most 0.2 lower than the refractive index of the anode electrode ANO. This can have the technical effect of reducing the amount of lights lost by the total reflection process inside the anode electrode ANO (or, light emitting diode OLE).

For example, the anode electrode ANO may have a refractive index of 2.0 to 2.3. The second planarization layer PL2 may have a refractive index of 1.8 to 2.0, which is the same as or about 0.2 different from the refractive index of the anode electrode ANO. In some implementations, the first planarization layer PL1 may have a refractive index of 1.3 to 1.5, which is at least 0.5 lower than that of the second planarization layer PL2.

In this case, the light emitted from the emission layer EL may propagate along light path ④ in FIG. 6. Lights generated from the emission layer EL may be radiated in a 180 degree range downward by the same mechanism as described above. Since the anode electrode ANO is made of a transparent conductive material and the second planarization layer PL2 has a similar refractive index with the anode electrode ANO, a large portion such as 90% to 98% of the lights may pass through the anode electrode ANO and through the second planarization layer PL2. The lights passing through the second planarization layer PL2 may enter into the first planarization layer PL1. As the first planarization layer PL1 has a refractive index of 1.4 to 1.5, a portion such as 60% to 70% of the incident lights into the first planarization layer PL1 may pass through the first planarization layer PL1, then may pass through the color filter CF placed underneath, and then be emitted outside the substrate 110.

However, among the lights incident to the second planarization layer PL2, a portion such as 30% to 40% of the lights that meet the total reflection condition at the interface between the second planarization layer PL2 and the first planarization layer PL1 may be re-entered into the anode electrode ANO, and then may be totally reflected at the upper surface of the anode electrode ANO or reflected by the cathode electrode CAT.

According to light path ④ shown in FIG. 6, unlike the light paths ① and ② shown in FIG. 5, the space where light emitted from the emission layer EL is totally reflected may be expanded, and the number of iterations of total reflection may be significantly reduced, due to the second planarization layer PL2 having a thickness of 1~1.5 µm. As a result, most of the lights emitted from the middle portion of the pixel and totally reflected may be reflected by the cathode electrode CAT having the micro-mirror structure MR and then may be directed in a downward direction.

The light emitting display device according to the first implementation may extract almost all of the lights generated from the emission layer EL, due to the second planarization layer PL protruded as an island shape and the cathode electrode CAT having the micro-mirror structure formed by the shape of the second planarization layer PL2. Accordingly, the light extraction efficiency may be further increased as compared to the structure shown in FIG. 5. In particular, since the second planarization layer PL2 may have a refractive index which is the same as the anode electrode ANO or slightly lower than the anode electrode ANO, the amount of the lights that may be trapped and lost inside the light emitting diode OLE may be reduced, so the light extraction efficiency may be enhanced.

In particular, by inducing total reflection between the second planarization layer PL2 and the first planarization layer PL1, the total reflection between the thin film layers below or under the planarization layer PL may be mitigated. As the result, a greater amount, e.g., more than 70%, of the lights emitted from the light emitting diode OLE may be extracted.

However, in some scenarios, lights may still remain trapped and extinguished within the second planarization layer PL2. For example, as shown in the optical path ⑤in FIG. 6, even though the total reflection condition of lights at the interface between the second planarization layer PL2 and the first planarization layer PL1 may be broken by the micro mirror MR, there may still remain lights which may not pass through the interface between the second planarization layer PL2 and the first planarization layer PL1 and then may be totally reflected. These lights may be dissipated into heat energy inside the second planarization layer PL2.

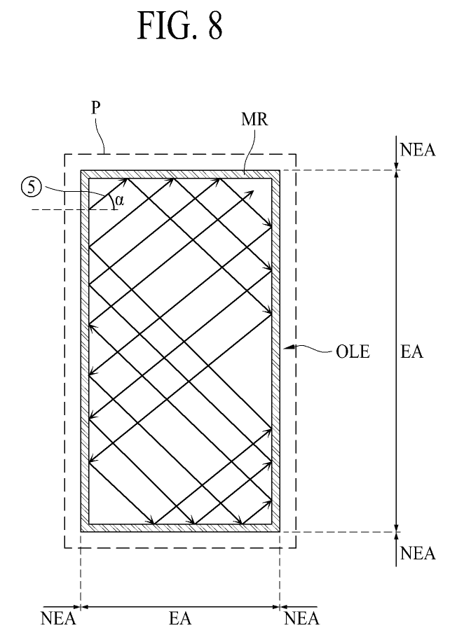

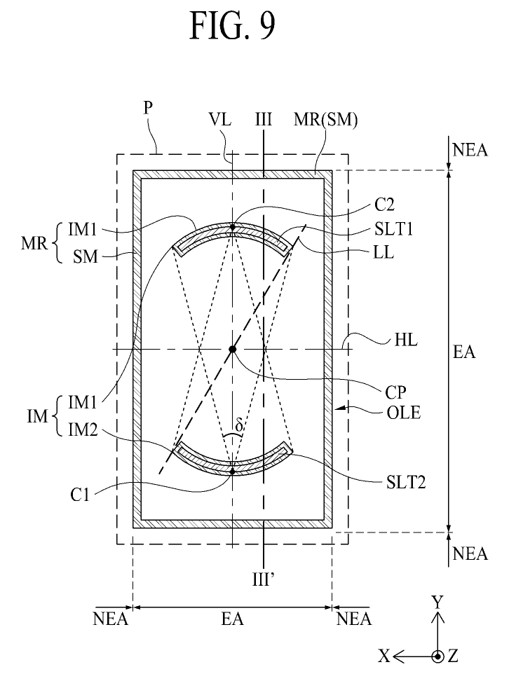

Referring to FIGS. 7 and 8, the mechanism by which lights may be trapped inside the second planarization layer PL2 will be explained. FIG. 7 is a schematic diagram illustrating an example of representative optical paths of the lights reflected by the side mirror in the light emitting display device according to a first implementation of the present disclosure. FIG. 8 is an enlarged cross-sectional view illustrating an example of optical paths of the lights trapped and extinguished inside the pixel on the plan view of the light emitting display device according to a first implementation of the present disclosure.

Referring to FIG. 7, lights reflected by the micro mirror will be explained. Lights reflected from the side mirror MR may include first group light trapped in the lights emitting diode OLE and propagating in a horizontal direction by total reflection and second group light reflected from the interface between the second planarization layer PL2 and the first planarization layer PL1. For convenience of explanation, these lights may be divided into a first light and a second light. The first light may be incident into the horizontal plane HPL toward the micro mirror MR and the second light may be reflected by the micro mirror MR and propagating on the reflective plane RPL.

The normal incident light ⓐ, which is incident vertically on the reflective plane RPL, may have an incident angle of 0 degree with respect to the normal direction of the reflective plane RPL. The normal incident light ⓐ may be reflected at the micro mirror MR and propagate downward as a normal reflected light ⓐ’. The normal reflected light ⓐ’ may pass through the interface between the second planarization layer PL1 and the first planarization layer PL1 and may be emitted to the outside of the substrate 110. (e.g., referring to the optical path ④ in FIG. 6).

Meanwhile, among the lights incident on the reflective plane RPL, an inclined incident light ⓑ incident with an incident angle α with respect to the normal direction of the reflective plane RPL may be reflected and propagate downward as an inclined reflected light ⓑ’. Here, the inclined reflected light ⓑ’ may have an reflection angle α corresponding to (or the same as) the incident angle α with respect to the normal reflected light ⓐ’ and may propagate toward the interface between the second planarization layer PL2 and the first planarization layer PL1. Here, when the reflection angle α satisfies the total reflection angle at the interface between the second planarization layer PL2 and the first planarization layer PL1, the light may be totally reflected to be emitted toward the cathode electrode CAT.

In this manner, the total reflection condition of light may be expected to be broken when the light is reflected by the micro mirror MR, but in actuality, since lights may have an inclined incident angle, the total reflection condition may not be broken when the inclined reflection angle satisfies the total reflection condition. An example of these lights may be as shown in FIG. 8, when observing on a plan view. When the incident angle α of light incident on the micro mirror MR inside the light emitting diode OLE surrounded by the micro mirror MR is greater than the total reflection angle at the interface between the second planarization layer PL2 and the first planarization layer PL1, the light may be totally reflected on the plane and may be trapped within the pixel P (or, the light emitting diode OLE) and then may be dissipated as heat energy. In FIG. 8, the optical path that is totally reflected inside the pixel P is shown by arrows. Totally reflected lights may refer to lights which are emitted at any location on the path indicated by these arrows and reflected along the arrows. Here, the lights trapped within the pixel P may include not only the lights which continue to be reflected along the reflection path, but may also be emitted from a point at the middle of one arrow and reflected several times (e.g., 1 to 4 times) before being dissipated (or, extinguished). In FIG. 8, the region including the micro mirror MR and the light emitting diode OLE may be defined as the emission area EA. The region other than the emission area EA may be defined as the non-emission area NEA.

The lights trapped inside the pixel P on the plan view may have an angle greater than the total reflection angle at the interface between the second planarization layer PL2 and the first planarization layer PL1. For example, the reflection angle of light trapped inside the pixel P may be greater than 50 degrees which is the total reflection angle between the second planarization layer PL2 and the first planarization layer PL1. Therefore, it can be preferable to provide a structure for breaking (or destroying) the total reflection angle for lights trapped inside the pixel P. Furthermore, in order to prevent total reflection even on the lower surface of the substrate 110, the total reflection angle between the substrate 110 and the air may be taken into consideration. For example, on a plan view, it can be preferable to further provide a structure for breaking the total reflection angle for lights trapped inside the pixel P and having an incident angle greater than 40 degree, which may be the total reflection angle between the substrate 110 and the air.

Some implementations can utilize a structure for extracting lights trapped within a pixel P on a plan view to the outside. For example, a light emitting display device according to an implementation of the present disclosure may further include an additional micro mirror at the center of a pixel P so as to destroy (or break) the total reflection condition in the middle of the path of the lights having an incident angle greater than the total reflection angle at the interface between the second planarization layer PL2 and the first planarization layer PL1 on a plan view.

### Second Implementation

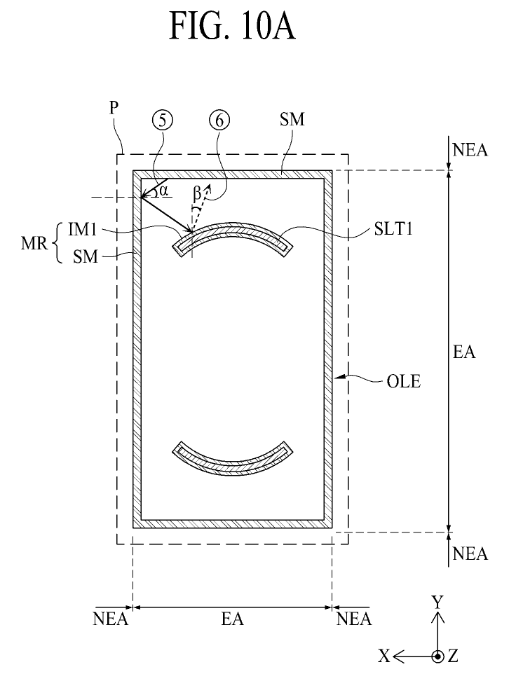

Hereinafter, referring to FIG. 9, an example a structure of a light emitting display device according to a second implementation of the present disclosure will be explained. FIG. 9 is a plan view illustrating an example of a structure of one pixel in a light emitting display device according to a second implementation of the present disclosure. FIG. 9 shows one pixel P on a plan view, for convenience. Pixel P may have an emission area EA and a non-emission area NEA. One light emitting diode OLE, as shown in FIG. 3, may be disposed within one pixel P. In FIG. 9, the emission area EA may include a side mirror SM and a light emitting diode OLE. The region outside of the emission area EA may be the non-emission area NEA.

A light emitting diode OLE according to the second implementation may have a rectangular shape in which a length in vertical direction (Y-axis direction) is longer than that of horizontal direction, on a plan view. The light emitting diode OLE may have four sides. The four sides may have two long sides and two short sides. Two long sides may include a left side and a right side which may run parallel along the Y-axis and may be spaced apart at a certain distance. Two short sides may include an upper side and a lower side which may run parallel along the X-axis and may be spaced apart at a certain distance.

The light emitting diode OLE according to the second implementation may include a micro mirror MR. In particular, the light emitting diode OLE may include a side mirror SM disposed at circumferences of the light emitting diode OLE and an internal mirror IM disposed at the middle portion of the light emitting diode OLE.

The side mirror SM may be disposed at four sides including the left side, the right side, the upper side and the lower side. However, it is not limited thereto. For example, when the ratio of the short side to the long side is 1:4 or more, the micro mirror MR may be disposed only at the left side and the right side having longer lengths, and may be omitted on the upper side and the lower sides having shorter lengths.

The internal mirror IM may be placed at a certain distance from the side mirror SM, in the central portion of the light emitting diode OLE. The internal mirror IM may have a concave portion, e.g., the internal mirror IM may have an arc shape. In some implementations, it can be preferable that at least two internal mirrors IM may be arranged.

As shown in FIG. 9, on a plan view, a first slit SLT1 may be disposed at the upper portion of the light emitting diode OLE, and a second slit SLT2 may be disposed at the lower portion of the light emitting diode OLE. The first internal mirror IM1 may be formed at the circumferences of the first slit SLT1, and the second internal mirror IM2 may be formed at the circumferences of the second slit SLT2.

The first internal mirror IM1 and the second internal mirror IM2 may be disposed of vertically symmetrical arrangement with respect to the horizontal center line HL. For example, the first internal mirror IM1 and the second internal mirror IM2 may have a left-right symmetric arrangement with respect to the vertical center line VL.

In addition, the left end point of the second internal mirror IM2 may be disposed on an extension of the straight line LL connecting from the right end point of the first internal mirror IM1 to the center point CP of the light emitting diode OLE. For example, the straight line connecting the right end point of the first internal mirror IM1 to the left end point of the second internal mirror IM2 may pass through the center point CP of the light emitting diode OLE. Therefore, the first internal mirror IM1 and the second internal mirror IM2 may be point symmetrical with respect to the central point CP of the light emitting diode OLE. The central point CP may be the intersection of the horizontal center line HL and the vertical center line VL.

The arc shapes of the first internal mirror IM1 and second internal mirror IM2 may be defined as portions of respective circles with respective center points. The center point of the circle that defines the arc shape may be referred to as an arc center point. For example, the arc center point C1 of the first internal mirror IM1 may be located in the middle of the second internal mirror IM2, e.g., at the midpoint of the second internal mirror IM2 that bisects the second internal mirror IM2 in two equal halves. Further, the arc center point C2 of the second internal mirror IM2 may be located at the midpoint of the first internal mirror IM1. The arc shape of each of the first internal mirror IM1 and second internal mirror IM2 may subtend a central arc angle, which is an angle formed by two radii connecting the center of the circle that defines the arc to the arc’s endpoints In some implementations, the central arc angle δ of the first internal mirror IM1 may be greater than or equal to 60 degrees and less than 120 degrees. Further, in some implementations, the central arc angle δ of the second internal mirror IM2 may be the same as the central arc angle δ of the first internal mirror IM1, i.e., it may be greater than or equal to 60 degrees and less than 120 degrees.

When the central arc angles of the first internal mirror IM1 and the second internal mirror IM2 are 120 degrees, then two arcs of the first internal mirror IM1 and the second internal mirror IM2 may meet each other. In some implementations, it can be preferable that the central arc angle of the two arcs may be less than 120 degrees so that the two arcs may not meet each other but may be separated from each other.

The central arc angles of the first internal mirror IM1 and the second internal mirror IM2 may be proportional to the lengths of the arc. In order to extract the lights trapped inside the light emitting diode OLE, it can be preferable that the arc lengths of the first internal mirror IM1 and the second internal mirror IM2 may be as long as possible. For example, the minimum arc length may be defined by the minimum central arc angle. The minimum central arc angle should be larger than 0 degrees. However, when the minimum central arc angle is too small, the arc length may be very small, and so it may not properly perform the function of breaking the total reflection condition. Therefore, it can be preferable that the central arc angle is at least 60 degrees. However, it is not limited thereto, and when the light emitting diode OLE has a very narrow width in the X-axis direction and a very long length in the Y-axis direction, the central arc angle may be less than 60 degrees.

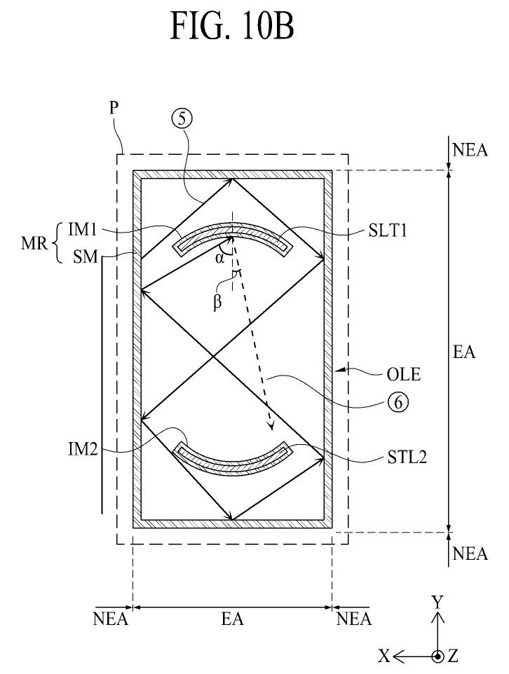

Referring to FIGS. 10A and 10B, an example of a mechanism by which light is emitted without being trapped inside a light emitting diode OLE by a micro mirror structure according to the second implementation will be explained. FIGS. 10A and 10B are diagrams for illustrating optical paths of the lights not trapped in the pixel and emitted out from the pixel on the plan view of the light emitting display device according to a second implementation of the present disclosure.

First, FIG. 10A illustrates an example of the case where the light is reflected by the outer parts of the first internal mirror IM1 and the second internal mirror IM2. For convenience, only the case of reflection of light from the outer part of the first internal mirror IM1 is explained, because the light is reflected in the same way on the outer part of the second internal mirror IM2. Inside the light emitting diode OLE on a plan view, when the incident angle α of the light traveling to the side mirror SM is greater than the total reflection angle at the interface between the first planarization layer PL1 and the second planarization layer PL2, the light may be trapped inside the light emitting diode OLE as being totally reflected along the optical path ⑤ shown in FIG. 8. Light reflected by the side mirror SM and incident on the outer surface of the first internal mirror IM1 with a total reflection angle may be reflected from the first internal mirror IM1 along the optical path ⑥ with a reflection angle β at which the total reflection angle condition is broken. For example, the reflection angle β may be smaller than the total reflection angle at the interface between the first planarization layer PL1 and the second planarization layer PL2. As a result, light is emitted to the outside after passing through the interface between the first planarization layer PL1 and the second planarization layer PL2. The optical path ⑥, the path of the emitted light, is indicated by a dotted arrow in FIG. 10A.

Next, FIG. 10B illustrates an example of the case where the light is reflected by the inner parts of the first internal mirror IM1 and the second internal mirror IM2. Light that is totally reflected along the optical path ⑤ may travel into the space between the first internal mirror IM1 and the second internal mirror IM2 as being repeatedly reflected by the side mirror SM. Finally, it is reflected on the internal surface of the first internal mirror IM1 or the second internal mirror IM2. Here, since the first internal mirror IM1 and/or the second internal mirror IM2 may have an arc shape, the reflection angle β may have a degree at which the total reflection is broken. For example, light trapped inside a light emitting diode OLE with an incident angle α satisfying the total reflection angle may travel along an optical path ⑥ with a reflection angle β at which the total reflection condition is broken, when reflected on the inner surface of the first internal mirror IM1 and/or the second internal mirror IM2. As a result, light is emitted to the outside after passing through the interface between the first planarization layer PL1 and the second planarization layer PL2.

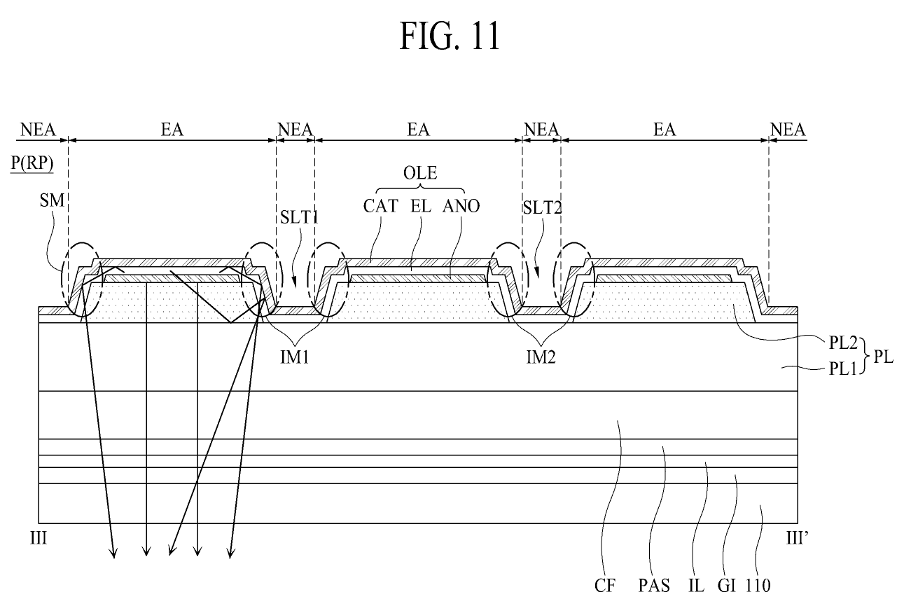

Hereinafter, referring to FIG. 11, an example of a cross-sectional structure of the light emitting display according to the second implementation will be explained. FIG. 11 is an enlarged cross-sectional view, taken along line III-III’ of FIG. 9, illustrating a structure of a light emitting display device according to a second implementation of the present disclosure. In FIG. 11, the region including the side mirror SM and the light emitting diode OLE may be defined as the emission area EA. The region except the emission area EA may be defined as the non-emission area NEA. The first slit SLT1 and the second slit SLT2 may be included into the non-emission area NEA. A first internal mirror IM1 may be formed at the circumferences of the first slit SLT1, and the first internal mirror IM1 may be included into the emission area EA. Similarly, the second internal mirror IM2 may also be included in the emission area EA.

The cross-sectional structure of the light emitting display device according to the second implementation shown in FIG. 11 may be very similar to that of the first implementation. The differences may be that the second implementation may further include the first slit SLT1 and the second slit SLT2, and the internal mirrors IM may be formed at each of the slits.

Referring to FIG. 11, a gate insulating layer GI, an intermediate insulating layer IL and a passivation layer PAS may be sequentially stacked on a substrate 110. FIG. 11 may show portions for the light emitting diode OLE only. Therefore, the driving element including the thin film transistors is not shown in FIG. 11. Since the driving element may be the same as that shown in FIG. 4, the detailed description is not duplicated here.

A color filter CF may be deposited on the passivation layer PAS. A first planarization layer PL1 may be deposited on the color filter CF. The first planarization layer PL1 may be deposited with a uniform thickness over the entire surface of the substrate 110 on which the color filter CF is formed. A second planarization layer PL2 may be deposited on the first planarization layer PL1. The second planarization layer PL2 may be disposed only at the location where the light emitting diode OLE is to be formed, and may have a shape that protrudes above the first planarization layer PL1.

The second planarization layer PL2 may include a sidewall and an upper surface. The sidewall may have a certain angle of inclination (or inclined angle) with the upper surface of the first planarization layer PL1. A first slit SLT1 and a second slit SLT2 may be formed interior of the second planarization layer PL2. For example, the first slit SLT1 and the second slit SLT2 may be formed by removing some inner portions of the second planarization layer PL2. Each of the first slit SLT1 and the second slit SLT2 may include a sidewall and a bottom surface. The sidewall of the slit may have a certain angle of inclination with the upper surface of the first planarization layer PL1. The bottom surface may be the upper surface of the first planarization layer PL1. For example, the first slit SLT1 and the second slit SLT2 may expose some of the upper surface of the first planarization layer PL1. As another example, the bottom surfaces of the first slit SLT1 and the second slit SLT2 may be located at a more sunken (or depressed) position downward from the upper surface of the first planarization layer PL1.

In some implementations, the second planarization layer PL2 may include two types of sidewalls: one type of sidewall is formed at the outer circumference (or edge) and another type of sidewall is formed at inner portion by the slit. These slits may have an inclined angle with respect to the upper surface of the first planarization layer PL1. For example, the inclined angle of the sidewall of the second planarization layer may be within a range of 50 degrees to 80 degrees, as explained in FIGS. 5 and 6.

An anode electrode ANO may be formed on the upper surface of the second planarization layer PL2. In some implementations, it can be preferable that the anode electrode ANO is not formed on the sidewall of the second planarization layer PL2. An emission layer EL may be deposited on the upper surfaces of the first planarization layer PL1, the second planarization layer PL2 and the anode electrode ANO. A cathode electrode CAT may be deposited on the emission layer EL. The cathode electrode CAT may be in surface contact with the emission layer EL.

The cathode electrode CAT may be deposited along the cross-sectional profile of the second planarization layer PL2. Therefore, a micro mirror MR may be formed at the sidewall of the second planarization layer PL2. The micro mirror MR may include a side mirror SM and an internal mirror IM. The internal mirror IM may include a first internal mirror IM1 and a second internal mirror IM2. The first internal mirror IM1 may be formed at the first slit SLT1. The second internal mirror IM2 may be formed at the second slit SLT2.

A light emitting diode OLE may be formed by stacking a structure of the anode electrode ANO, the emission layer EL and the cathode electrode CAT. The side mirror SM may be formed at the outer circumferences (or edges) of the light emitting diode OLE. The first internal mirror IM1 and the second internal mirror IM2 may be formed inner portions of the light emitting diode OLE. Among the lights emitted from the emission layer EL, the lights traveling downward may be emitted to the outside of the substrate 110. Lights traveling upward may be reflected downward by the cathode electrode CAT and emitted outside the substrate 110.

Meanwhile, lights traveling along the horizontal direction inside the light emitting diode OLE may be reflected by the side mirror SM and the internal mirrors IM1 and IM2. These reflected lights may be redirected to travel downward and may be emitted outside the substrate 110.

Among the lights emitted from the emission layer EL, lights satisfying the total reflection condition at the interface between the first planarization layer PL1 and the second planarization layer PL2 may be reflected upward. These lights that are reflected by total reflection may be re-reflected by the cathode electrode CAT, and may travel downward. In this scenario, as the total reflection condition may be broken by the side mirror SM and/or the internal mirror IM, most of the totally reflected lights may be emitted outside the substrate 110.

However, as explained with FIGS. 7 and 8, there may still be lights trapped inside the second planarization layer PL2 on a plan view. However, the second implementation may further include internal mirror IM. In particular, the internal mirror IM may have a curved shape, so that the reflection angle of the light greater than the total reflection angle between the second planarization layer PL2 and the first planarization layer PL1 may be converted into a reflection angle less than the total reflection angle. As the result, most of lights may not be trapped inside the second planarization layer PL2 but may be extracted outside the substrate 110.

Here, for convenience of explanation, only the case of extracting more lights trapped inside the second planarization layer PL2 has been described. However, it is not limited thereto, and the lights totally reflected from the bottom surface of the first planarization layer PL1, the bottom surface of the passivation layer PAS, and/or the bottom surface of the substrate 110 may also be emitted outside the substrate 110 as the total reflection condition may be broken by the internal mirror IM.

In summary, the light emitting display device according to the second implementation may extract not only lights which may be trapped and dissipated inside the light emitting diode OLE, but also lights which may be trapped and dissipated between the planarization layer PL and the substrate 110. As a result, light extraction efficiency may be improved, enabling enhanced luminance to be provided with the same power consumption. In other words, in providing the same luminance, less power consumption may be required, enabling low-power consumption.

In the following implementations, various structures of a side mirror arranged at circumferences of a light emitting diode OLE and an internal mirror arranged inside the light emitting diode OLE will be described. In particular, following implementations show various examples of the diversity of the structure of the internal mirror.

### Third Implementation

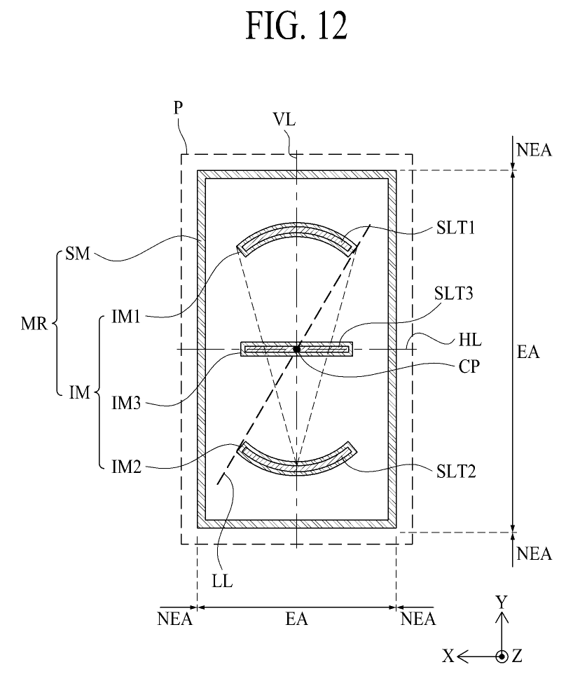

Hereinafter, referring to FIG. 12, a structure of a light emitting display device according to a third implementation will be explained. FIG. 12 is an enlarged plan view illustrating a structure of one pixel in a light emitting display device according to a third implementation of the present disclosure. A pixel P may include an emission area EA and a non-emission area NEA. In FIG. 12, a region including the side mirror SM and the light emitting diode OLE may be defined as the emission area EA. A region excluding the emission area EA may be defined as the non-emission area NEA. In addition, regions where a first slit SLT1, a second slit SLT2 and a third slit SLT3 are formed may be included into the non-emission area NEA. However, regions where a first internal mirror IM1, a second internal mirror IM2 and a third internal mirror IM3 are formed may be included into the emission area EA.

The light emitting display device according to the third implementation shown in FIG. 12 may include a light emitting diode OLE formed in a pixel P. The light emitting diode OLE according to the third implementation may include a micro mirror MR. For example, the micro mirror MR may include a side mirror SM disposed at outer circumferences and an internal mirror IM disposed near the middle of the pixel P.

The side mirror SM may be disposed at each of four sides including a left side, a right side, an upper side and a lower side. The internal mirror IM may be placed at a certain distance from the side mirror SM and inside of the light emitting diode OLE. The internal mirror IM may include a first internal mirror IM1 and a second internal mirror IM2 having arc shapes and a third internal mirror IM3 having linear segment shape.

As shown in FIG. 12, on a plan view, a first slit SLT1 may be formed at upper portion of the light emitting diode OLE, a second slit SLT2 may be formed at lower portion of the light emitting diode OLE, and a third slit SLT3 may be formed at the center of the light emitting diode OLE. The first slit SLT1 and the second slit SLT2 may have arc shapes facing each other. The third slit SLT3 may have a short linear segment shape disposed at the central portion between the first slit SLT1 and the second slit SLT2. A first internal mirror IM1 may be formed at circumferences of the first slit SLT1 and a second internal mirror IM2 may be formed at circumferences of the second slit SLT2. In addition, a third internal mirror IM3 may be formed at circumferences of the third slit SLT3.

In some implementations, the third internal mirror IM3 may be disposed on the horizontal center line HL. The first internal mirror IM1 and the second internal mirror IM2 may have vertical symmetry with respect to the third internal mirror IM3. As such, the first internal mirror IM1, the second internal mirror IM2 and the third internal mirror IM3 may have bilateral symmetry with respect to the vertical center line VL. Further, the first internal mirror IM1, the second internal mirror IM2 and the third internal mirror IM3 may have point symmetry with respect to the central point CP. The center point CP may be an intersection point of the horizontal center line HL and the vertical center line VL.

In addition, a left end point of the second internal mirror IM2 may be located on an extension of the straight line LL connecting a right end point of the first internal mirror IM1 to the center point CP of the light emitting diode OLE. As such, a straight line connecting the right end point of the first internal mirror IM1 to the left end point of the second internal mirror IM2 may pass through the center point CP of the light emitting diode OLE.

As described above, the arc shapes of the first internal mirror IM1 and second internal mirror IM2 may be defined as portions of respective circles with respective center points, referred to herein as an arc center point. For example, an arc center point C1 of the first internal mirror IM1 may be located at the midpoint of the second internal mirror IM2 that bisects the second internal mirror IM2 in two equal halves. Similarly, an arc center point C2 of the second internal mirror IM2 may be located at the midpoint of the first internal mirror IM1. For example, the central arc angle δ of the first internal mirror IM1 may be greater than or equal to 60 degrees and less than 120 degrees. Similarly, the central arc angle of the second internal mirror IM2 may be greater than or equal to 60 degrees and less than 120 degrees, which is the same as the central arc angle δ of the first internal mirror IM1. When the central arc angles of the first internal mirror IM1 and the second internal mirror IM2 are 120 degrees, the two arcs may meet. In some implementations, it can be preferable that the central arc angle of the two arcs may be less than 120 degrees so that the two arcs may not meet each other but may be separated from each other.

The third implementation may have a structure in which an additional internal mirror having a line segment shape may be further included between at least two internal mirrors having arc shapes. When only the line segment shaped internal mirror is placed excluding the arc shaped internal mirrors, the total reflection condition may not be broken. Therefore, the first internal mirror IM1 and the second internal mirror IM2 having arc shapes are included in the light emitting display device according to some implementations of the present disclosure.

The description of the optical path for extracting light emitted from the light emitting diode OLE according to the third implementation to the outside may be the same as that of the second implementation, so the same explanation will not be duplicated. The light emitting display device according to the third implementation may emit lights to the outside that may be totally reflected and dissipated in flat layers disposed under the light emitting diode OLE and the second planarization layer PL2.

As the result, light extraction efficiency may be improved, enabling enhanced luminance to be provided with the same power consumption. In other words, in providing the same luminance, less power consumption may be required, enabling low-power consumption.

### Fourth Implementation

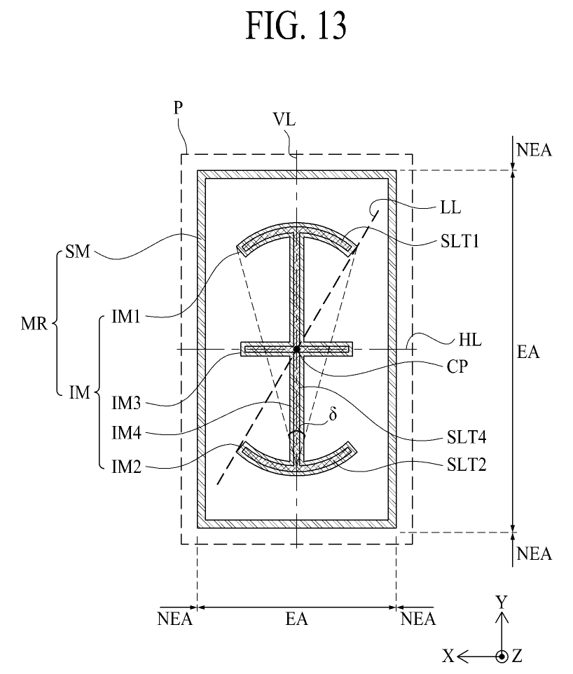

Hereinafter, referring to FIG. 13, a structure of a light emitting display device according to a fourth implementation will be explained. FIG. 13 is an enlarged plan view illustrating a structure of one pixel in a light emitting display device according to a fourth implementation of the present disclosure. A pixel P may include an emission area EA and a non-emission area NEA. In FIG. 13, a region including the side mirror SM and the light emitting diode OLE may be defined as the emission area EA. A region excluding the emission area EA may be defined as the non-emission area NEA. In addition, regions where a first slit SLT1, a second slit SLT2, a third slit SLT3 and a fourth slit SLT4 are formed may be included into the non-emission area NEA. However, regions where a first internal mirror IM1, a second internal mirror IM2, a third internal mirror IM3 and a fourth internal mirror IM4 are formed may be included into the emission area EA.

A structure of the light emitting diode OLE included in the light emitting display according to the fourth implementation may be very similar to the light emitting diode OLE according to the third implementation. In the fourth implementation, a fourth internal mirror IM4 may be further included.

For example, the light emitting diode OLE according to the fourth implementation may include micro mirror MR. In particular, the micro mirror MR may include a side mirror disposed at outer circumferences of the light emitting diode OLE and an internal mirror IM disposed inside of the light emitting diode OLE.

The side mirror SM may be disposed at each of four sides of the light emitting diode OLE including a left side, a right side, an upper side and a lower side. The internal mirror IM may be placed at a certain distance from the side mirror SM and inside of the light emitting diode OLE. The internal mirror IM may include a first internal mirror IM1 and a second internal mirror IM2 having arc shapes, a third internal mirror IM3 having a horizontal segment shape, and a fourth internal mirror IM4 having a vertical segment shape.

As shown in FIG. 13, on a plan view, a first slit SLT1 may be formed at upper portion of the light emitting diode OLE, a second slit SLT2 may be formed at lower portion of the light emitting diode OLE, and a third slit SLT3 and a fourth slit SLT4 may be formed at the center of the light emitting diode OLE. The first slit SLT1 and the second slit SLT2 may have arc shapes facing each other. The third slit SLT3 may have a short horizontal segment shape disposed at the central portion between the first slit SLT1 and the second slit SLT2. The fourth slit SLT4 may have a short vertical segment shape connecting the midpoint of the first slit SLT1 to the midpoint of the second slit SLT2. Therefore, the fourth slit SLT4 may intersect with the third slit SLT3 in a ‘+’ shape.

A first internal mirror IM1 may be formed at circumferences of the first slit SLT1, and a second internal mirror IM2 may be formed at circumferences of the second slit SLT2. In addition, a third internal mirror IM3 may be formed at circumferences of the third slit SLT3, and a fourth internal mirror IM4 may be formed at circumferences of the fourth slit SLT4. The third internal mirror IM3 may be disposed on the horizontal center line HL. The fourth internal mirror IM4 may be disposed on the vertical center line VL.

The first internal mirror IM1, the second internal mirror IM2 and the fourth internal mirror IM4 may have vertical symmetry with respect to the third internal mirror IM3. For example, the first internal mirror IM1, the second internal mirror IM2 and the third internal mirror IM3 may have bilateral symmetry with respect to the fourth internal mirror IM4. Further, the first internal mirror IM1, the second internal mirror IM2, the third internal mirror IM3 and the fourth internal mirror IM4 may have point symmetry with respect to the central point CP. The center point CP may be an intersection point of the horizontal center line HL and the vertical center line VL.

In addition, a left end point of the second internal mirror IM2 may be located on an extension of the straight line LL connecting a right end point of the first internal mirror IM1 to the center point CP of the light emitting diode OLE. For example, a straight line connecting the right end point of the first internal mirror IM1 to the left end point of the second internal mirror IM2 may pass through the center point CP of the light emitting diode OLE.

As described above, the arc shapes of the first internal mirror IM1 and second internal mirror IM2 may be defined as portions of respective circles with respective center points, referred to herein as an arc center point. For example, an arc center point C1 of the first internal mirror IM1 may be located at the midpoint of the second internal mirror IM2 that bisects the second internal mirror IM2 in two equal halves. Similarly, an arc center point C2 of the second internal mirror IM2 may be located at the midpoint of the first internal mirror IM1. For example, the central arc angle δ of the first internal mirror IM1 may be greater than or equal to 60 degrees and less than 120 degrees. Similarly, the central arc angle of the second internal mirror IM2 may be greater than or equal to 60 degrees and less than 120 degrees, which is the same as the central arc angle δ of the first internal mirror IM1. When the central arc angles of the first internal mirror IM1 and the second internal mirror IM2 are 120 degrees, the two arcs may meet. In some implementations, it can be preferable that the central arc angle of the two arcs may be less than 120 degrees so that the two arcs may not meet each other but may be separated from each other.

In some scenarios, in the fourth implementation, the light emitting diode OLE may have a structure in which the third internal mirror IM3 is removed. For example, the internal mirror IM of the fourth implementation may include a first internal mirror IM1, the second internal mirror IM2, and the fourth internal mirror IM4, but not the third internal mirror IM3.

The description of the optical path for extracting light emitted from the light emitting diode OLE according to the fourth implementation to the outside may be the same as that of the second implementation, so the same explanation will not be duplicated. The light emitting display device according to the fourth implementation may emit lights to the outside that may be totally reflected and dissipated in flat layers disposed under the light emitting diode OLE and the second planarization layer PL2.

As the result, light extraction efficiency may be improved, enabling enhanced luminance to be provided with the same power consumption. In other words, in providing the same luminance, less power consumption may be required, enabling low-power consumption.

### Fifth Implementation

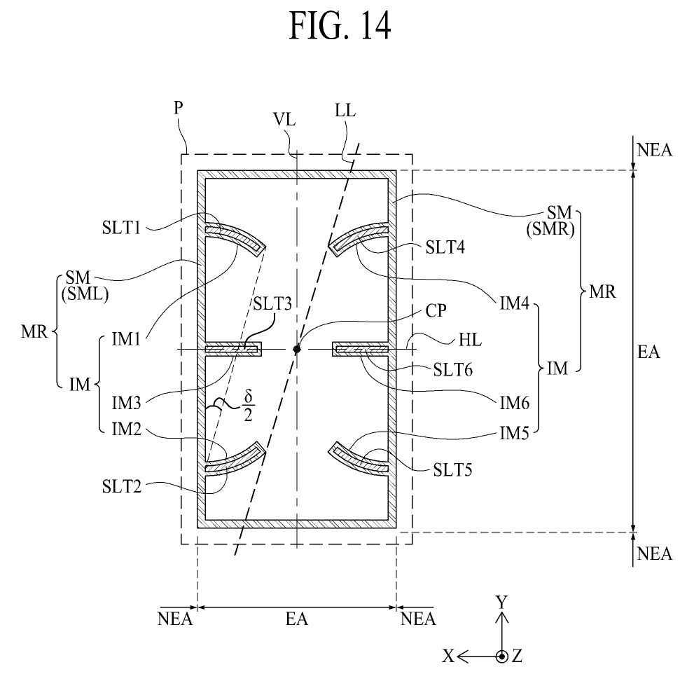

Hereinafter, referring to FIG. 14, an example of a structure of a light emitting display device according to a fifth implementation will be explained. FIG. 14 is an enlarged plan view illustrating a structure of one pixel in a light emitting display device according to a fifth implementation of the present disclosure. A pixel P may include an emission area EA and a non-emission area NEA. In FIG. 14, a region including the side mirror SM and the light emitting diode OLE may be defined as the emission area EA. A region excluding the emission area EA may be defined as the non-emission area NEA. In addition, regions where a first slit SLT1, a second slit SLT2, a third slit SLT3, a fourth slit SLT4 a fifth slit SLT5 and a sixth slit SLT6 are formed may be included into the non-emission area NEA. However, regions where a first internal mirror IM1, a second internal mirror IM2, a third internal mirror IM3, a fourth internal mirror IM4, a fifth internal mirror IM5 and a sixth internal mirror IM6 are formed may be included into the emission area EA.

A structure of the light emitting diode OLE included in the light emitting display according to the fifth implementation may be very similar to the light emitting diode OLE according to the third implementation. In the fifth implementation, by dividing the micro mirrors MR according to the third implementation into two halves with respect to the vertical center line VL, these divided micro mirrors may be arranged as left mirrors including left side mirror SML, first internal mirror IM1, second internal mirror IM2 and third internal mirror IM3, and right mirrors SMR including right side mirror SMR, fourth internal mirror IM4, fifth internal mirror IM5 and sixth internal mirror IM6, respectively.

For example, the light emitting diode OLE according to the fifth implementation may include a micro mirror MR. In particular, the micro mirror MR may include a side mirror SM disposed at outer circumferences and an internal mirror IM disposed inside of the light emitting diode OLE.

The side mirror SM may be disposed at each of four sides of the light emitting diode OLE including a left side, a right side, an upper side and a lower side. In particular, the side mirror SM may include a left side mirror SML disposed at the left side of the light emitting diode OLE, and a right side mirror SMR disposed at the right side of the light emitting diode OLE.

The internal mirror IM may include a left internal mirror with one end connected to the left side mirror SML and extended inside the light emitting diode OLE, and a right internal mirror with one end connected to the right side mirror SMR and extended inside the light emitting diode OLE. For example, the internal mirror IM may include a first internal mirror IM1, a second internal mirror IM2, a fourth internal mirror IM4 and a fifth internal mirror IM5 having arc shapes, and a third internal mirror IM3 and a sixth internal mirror IM6 having segment shapes.

As shown in FIG. 14, on a plan view, a first slit SLT1 may be formed at upper left side of the light emitting diode OLE, a second slit SLT2 may be formed at lower left side of the light emitting diode OLE, and a third slit SLT3 may be formed at center left side of the light emitting diode OLE. Further, a fourth slit SLT4 may be formed at upper right side of the light emitting diode OLE, a fifth slit SLT5 may be formed at lower right side of the light emitting diode OLE, and a sixth slit SLT6 may be formed at center right side of the light emitting diode OLE. The first slit SLT1 and the second slit SLT2 may have arc shapes facing each other. The third slit SLT3 may have a short segment shape at middle portion between the first slit SLT1 and the second slit SLT2. Similarly, the fourth slit SLT4 and the fifth slit SLT5 may have arc shapes facing each other. The sixth slit SLT6 may have a short segment shape at middle portion between the fourth slit SLT4 and the fifth slit SLT5.

A first internal mirror IM1 may be formed at circumferences of the first slit SLT1, and a second internal mirror IM2 may be formed at circumferences of the second slit SLT2. A third internal mirror IM3 may be formed at circumferences of the third slit SLT3. Similarly, a fourth internal mirror IM4 may be formed at circumferences of the fourth slit SLT4, and a fifth internal mirror IM5 may be formed at circumferences of the fifth slit SLT5. A sixth internal mirror IM6 may be formed at circumferences of the sixth slit SLT6. The third internal mirror IM3 and the sixth mirror IM6 may be disposed on the horizontal center line HL.

The first internal mirror IM1 and the second internal mirror IM2 may have vertical symmetry with respect to the third internal mirror IM3. Similarly, the fourth internal mirror IM4 and the fifth internal mirror IM5 may have vertical symmetry with respect to the sixth internal mirror IM6. For example, the first internal mirror IM1, the second internal mirror IM2 and the third internal mirror IM3 may have bilateral symmetry to the forth internal mirror IM4, the fifth internal mirror IM5 and the sixth internal mirror IM6, respectively, with respect to the vertical center line VL. Further, the first internal mirror IM1, the second internal mirror IM2, the third internal mirror IM3, the fourth internal mirror IM4, the fifth internal mirror IM5 and the sixth internal mirror IM6 may have point symmetry with respect to the central point CP. The center point CP may be an intersection point of the horizontal center line HL and the vertical center line VL.

In addition, a right end point of the second internal mirror IM2 may be located on an extension of the straight line LL connecting a left end point of the fourth internal mirror IM4 to the center point CP of the light emitting diode OLE. For example, a straight line connecting the left end point of the fourth internal mirror IM4 to the right end point of the second internal mirror IM2 may pass through the center point CP of the light emitting diode OLE.

An arc center point of the first internal mirror IM1 may be located at an intersection point where the second internal mirror IM2 meets the left side mirror SML. An arc center point of the second internal mirror IM2 may be located at an intersection point where the first internal mirror IM1 meets the left side mirror SML. Similarly, an arc center point of the fourth internal mirror IM4 may be located at an intersection point where the fifth internal mirror IM5 meets the right side mirror SMR. An arc center point of the fifth internal mirror IM5 may be located at an intersection point where the fourth internal mirror IM1 meets the right side mirror SMR.

In some implementations, the central arc angle δ/2 of the first internal mirror IM1 may be less than or equal to 60 degrees. Further, the central arc angle δ/2 of the second internal mirror IM2 may be less than or equal to 60 degrees, which is the same as the central arc angle δ/2 of the first internal mirror IM1. Similarly, the central arc angle δ/2 of the fourth internal mirror IM4 may be less than or equal to 60 degrees. The central arc angle δ/2 of the fifth internal mirror IM5 may be less than or equal to 60 degrees, which is the same as the central arc angle δ/2 of the fourth internal mirror IM4.

The description of the optical path for extracting light emitted from the light emitting diode OLE to the outside according to the fifth implementation may be the same as that of the second implementation, so the same explanation will not be duplicated. The light emitting display device according to the fifth implementation may emit lights to the outside that may otherwise be totally reflected and dissipated in flat layers disposed under the light emitting diode OLE and the second planarization layer PL2.

As the result, light extraction efficiency may be improved, enabling enhanced luminance to be provided with the same power consumption. In other words, in providing the same luminance, less power consumption may be required, enabling low-power consumption.

### Sixth Implementation

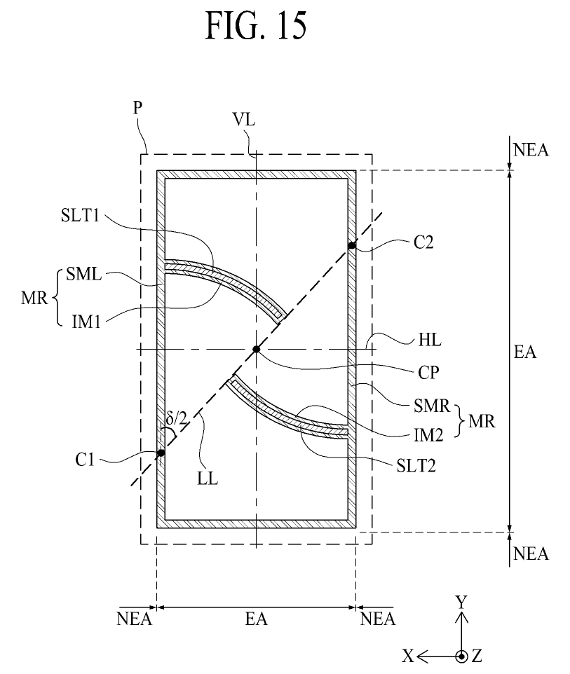

Hereinafter, referring to FIG. 15, an example of a structure of a light emitting display device according to a sixth implementation will be explained. FIG. 15 is an enlarged plan view illustrating a structure of one pixel in a light emitting display device according to a sixth implementation of the present disclosure. A pixel P may include an emission area EA and a non-emission area NEA. In FIG. 15, a region including the side mirror SM and the light emitting diode OLE may be defined as the emission area EA. A region excluding the emission area EA may be defined as the non-emission area NEA. In addition, regions where a first slit SLT1 and a second slit SLT2 are formed may be included into the non-emission area NEA. However, regions where a first internal mirror IM1 and a second internal mirror IM2 are formed may be included into the emission area EA.

The light emitting diode OLE according to the sixth implementation may include a micro mirror MR. In particular, the micro mirror MR may include a side mirror SM disposed at outer circumferences and an internal mirror IM disposed inside of the light emitting diode OLE.

The side mirror SM may be disposed at each of four sides of the light emitting diode OLE including a left side, a right side, an upper side and a lower side. However, it is not limited thereto. For example, when the ratio of the short side to the long side is 1:4 or more, the side mirror SM may be placed only on the long left and right sides, but not on the short upper and lower sides. In particular, the side mirror SM may include a left side mirror SML disposed at the left side of the light emitting diode OLE, and a right side mirror SMR disposed at the right side of the light emitting diode OLE

The internal mirror IM may include a first internal mirror IM1 and a second external mirror IM2. The first internal mirror IM1 may have one end connected to the left side mirror SML and have an arc shape extending inside the light emitting diode OLE. The second internal mirror IM2 may have one end connected to the right side mirror SMR and have an arc shape extending inside the light emitting diode OLE.

As shown in FIG. 15, on a plan view, a first slit SLT1 may be formed as being connected to the left side mirror SML at the upper portion of the light emitting diode OLE, and a second slit SLT2 may be formed as being connected to the right side mirror SMR at the lower portion of the light emitting diode OLE. A first internal mirror IM1 may be formed at circumferences of the first slit SLT1, and a second internal mirror IM2 may be formed at circumferences of the second slit SLT2.

An arc center point C1 of the first internal mirror IM1 may be located on the left side mirror SML. An arc center point C2 of the second internal mirror IM2 may be located on the right side mirror SMR. For example, a straight line LL connecting the arc center point C1 of the first internal mirror IM1 to the arc center C2 of the second internal mirror IM2 may pass the center point CP of the light emitting diode OLE. Further, the straight line LL may pass a right end point of the first internal mirror IM1 and a left end point of the second internal mirror IM2. For example, a straight line connecting the right end point of the first internal mirror IM1 to the left end point of the second internal mirror IM2 may pass the center point CP of the light emitting diode OLE.

In some implementations, the central arc angle δ/2 of the first internal mirror IM1 may be less than or equal to 60 degrees. Further, the central arc angle δ/2 of the second internal mirror IM2 may be less than or equal to 60 degrees, which is the same as the central arc angle δ/2 of the first internal mirror IM1. However, it is not limited thereto, and the central arc angle δ/2 of the first internal mirror IM1 may be greater than 60 degrees. For example, the right end point of the first internal mirror IM1 and the left end point of the second internal mirror IM2 may be located on the horizontal center line HL. Otherwise, the right end point of the first internal mirror IM1 may be positioned adjacent to the second internal mirror IM2 after passing the horizontal center line HL. In this case, the left end point of the second internal mirror IM2 may be positioned adjacent to the first internal mirror IM1 after passing the horizontal center line HL.

In a further example, the right end point of the first internal mirror IM1 may contact the second internal mirror IM2, and the left end point of the second internal mirror IM2 may contact the first internal mirror IM1. In a structure in which the first internal mirror IM1 and the second internal mirror IM2 meet each other, the areas of the first slit SLT1 and the second slit SLT2 may increase. Since the anode electrode ANO is not formed at these areas of the slits, these areas may be included into the non-emission area NEA. Therefore, in order to ensure enough wide emission area EA, according to some implementations it can be preferable that the first internal mirror IM1 and the second internal mirror IM2 may have a minimum length or area.

Consequently, the first internal mirror IM1 and the second internal mirror IM2 may have point symmetry with respect to the center point CP. In some implementations, an additional internal mirror having a cylindrical shape may be disposed at the center point CP. For this case, the arrangement of the internal mirrors may maintain a structure that is point symmetry with respect to the center point CP.

The description of the optical path for extracting light emitted from the light emitting diode OLE to the outside according to the sixth implementation may be the same as that of the second implementation, so the same explanation will not be duplicated. The light emitting display device according to the sixth implementation may emit lights to the outside that may otherwise be totally reflected and dissipated in flat layers disposed under the light emitting diode OLE and the second planarization layer PL2.

As the result, light extraction efficiency may be improved, enabling enhanced luminance to be provided with the same power consumption. In other words, in providing the same luminance, less power consumption may be required, enabling low-power consumption.

### Seventh Implementation

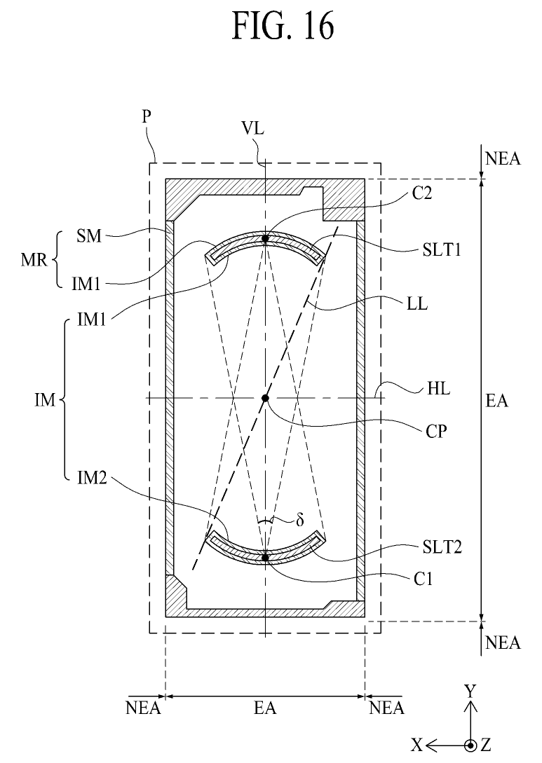

Hereinafter, referring to FIG. 16, an example of a structure of a light emitting display device according to a seventh implementation will be explained. FIG. 16 is an enlarged plan view illustrating a structure of one pixel in a light emitting display device according to a seventh implementation of the present disclosure. A pixel P may include an emission area EA and a non-emission area NEA. In FIG. 16, a region including the side mirror SM and the light emitting diode OLE may be defined as the emission area EA. A region excluding the emission area EA may be defined as the non-emission area NEA. In addition, regions where a first slit SLT1 and a second slit SLT2 are formed may be included into the non-emission area NEA. However, regions where a first internal mirror IM1 and a second internal mirror IM2 are formed may be included into the emission area EA.

A structure of a light emitting display device according to the seventh implementation may be very similar to the light emitting display device according to the second implementation shown in FIG. 9. The difference is that the seventh implementation may not include the side mirror SM at the upper side and the lower side. Therefore, descriptions of drawing symbols that are shown in FIG. 16 which are the same as in the second implementation are not repeated here.

The light emitting diode OLE according to the seventh implementation may have a rectangular shape with a longer length in the vertical (Y-axis) direction on a plan view. The light emitting diode OLE may have four sides. The four sides may include two longer sides and two shorter sides. The two longer sides may include a left side and a right side which run parallel along the Y-axis and may be spaced apart from each other by a certain distance corresponding to the length of the shorter side. The two shorter sides may include an upper side and a lower side which run parallel along the X-axis and may be spaced apart from each other by a certain distance corresponding to the length of longer side.

The light emitting diode OLE according to the seventh implementation may include a micro mirror MR. In particular, the micro mirror MR may include a side mirror SM disposed at the outer circumference of the light emitting diode OLE and an internal mirror IM inside the light emitting diode OLE.

The side mirror SM may include two side mirrors which are disposed at the left side and the right side of the light emitting diode OLE. For example, when the ratio of the short side to the long side is 1:4 or more, the side mirror SM may be disposed only at the long sides including the left side and the right side, but not disposed at the short sides including the upper side and the lower side.

The internal mirror IM may be placed at a certain distance from the side mirror SM and inside of the light emitting diode OLE. In some implementations, it can be preferable that at least two internal mirrors IM having arc shapes may be disposed in the light emitting diode OLE. The internal mirror IM may include a first internal mirror IM1 and a second internal mirror IM2.

The first internal mirror IM1 and the second internal mirror IM2 may have the same structure explained in the second implementation as shown in FIG. 9. Therefore, the following description will focus on the features that are relevant to the explanation in this implementation.

The first internal mirror IM1 and the second internal mirror IM2 may have vertical symmetry with respect to the horizontal center line HL. For example, the first internal mirror IM1 and the second internal mirror IM2 may have bilateral symmetry with respect to the vertical center line VL. Further, the first internal mirror IM1 and the second internal mirror IM2 may have point symmetry with respect to the central point CP. The center point CP may be an intersection point of the horizontal center line HL and the vertical center line VL.

In addition, a left end point of the second internal mirror IM2 may be located on an extension of the straight line LL connecting a right end point of the first internal mirror IM1 to the center point CP of the light emitting diode OLE. For example, a straight line connecting the right end point of the first internal mirror IM1 to the left end point of the second internal mirror IM2 may pass through the center point CP of the light emitting diode OLE.

In some implementations, the internal mirror IM may have the same structure as the internal mirror IM explained in the third implementation shown in FIG. 12. As another example, the internal mirror IM may have the same structure as the internal mirror IM explained in the fourth implementation shown in FIG. 13. As yet another example, the internal mirror IM may have the same structure as the internal mirror IM explained in the fifth implementation shown in FIG. 14. Further, the internal mirror IM may have the same structure as the internal mirror IM explained in the sixth implementation shown in FIG. 15.

The description of the optical path for extracting light emitted from the light emitting diode OLE to the outside according to the seventh implementation may be the same as that of the second implementation, so the same explanation will not be duplicated. The light emitting display device according to the seventh implementation may emit lights to the outside that may otherwise be totally reflected and dissipated in flat layers disposed under the light emitting diode OLE and the second planarization layer PL2.

As the result, light extraction efficiency may be improved, enabling enhanced luminance to be provided with the same power consumption. In other words, in providing the same luminance, less power consumption may be required, enabling low-power consumption.

In the descriptions from the first implementation to the seventh implementation, the light emitting display device may have a bank-less structure in which a bank for defining the emission area by covering the circumferential edges of the anode electrode ANO is not formed. For example, such a bank may be an insulating layer for defining the emission area by covering the circumferential edges of the anode electrode ANO to expose the middle portion of the anode electrode ANO. The bank may as be referred to as a pixel defining layer. In some implementations, the light emitting display device according to the present disclosure may not have bank at all. However, it is not limited thereto, and in some implementations, a bank may be disposed at the upper side and lower side of the pixel where the driving element is disposed, except the left side and the right side of the pixel. Further, even for the case of having a bank surrounding the pixel, the structure described in the various implementations of the present disclosure may be applied. In some scenarios, implementations of the present disclosure that are described in the bank-less structure may be advantageous for low-power operation and may ensure the maximum aperture ratio.

A light emitting display device according to various implementations of the present disclosure may include: a substrate, a plurality of pixels, a light emitting diode, a side mirror, a first internal mirror and a second internal mirror. The plurality of pixels is arrayed on the substrate. Each of the pixels has an emission area and a non-emission area. The light emitting diode is disposed within the each pixel. The side mirror is disposed at outer circumferences of the light emitting diode. The first internal mirror has an arc shape and is disposed inside the light emitting diode. The second internal mirror has the arc shape and is disposed inside the light emitting diode. One end point of the second internal mirror is located on an extension of a straight line connecting one end point of the first internal mirror to a center point of the light emitting diode.

For an implementation, the internal mirror further includes: a third internal mirror having a horizontal segment shape passing the center point of the light emitting diode.

For an implementation, the internal mirror further includes: a fourth internal mirror having a vertical segment shape passing the center point of the light emitting diode.

For an implementation, the first internal mirror contacts a left mirror disposed at a left side of the light emitting diode and extends inside the light emitting diode. The second internal mirror contacts a right mirror disposed at a right side of the light emitting diode and extends inside the light emitting diode.

For an implementation, an arc center of the first internal mirror is located at a center point of the second internal mirror. An arc center of the second internal mirror is located at a center point of the first internal mirror.

For an implementation, a first arc center angle of the first internal mirror and a second arc center angle of the second internal mirror are greater than or equal to 60 degree and less than 120 degree.

For an implementation, the first internal mirror and the second internal mirror have a vertical symmetry with respect to a horizontal line passing the center point of the light emitting diode.

For an implementation, the first internal mirror and the second internal mirror have a bilateral symmetry with respect to a vertical line passing the center point of the light emitting diode.

For an implementation, the first internal mirror and the second internal mirror have a point symmetry with respect to the center point of the light emitting diode.

For an implementation, the light emitting display device further comprises: a first planarization layer having a first thickness on the substrate; a second planarization layer having a second thickness, and extruded over the first planarization layer within the emission area; an anode electrode disposed within the emission area on the second planarization layer; an emission layer on the anode electrode, the first planarization layer and the second planarization layer; and a cathode electrode on the emission layer.

For an implementation, the light emitting display device further comprises: a first slit and a second slit formed at a middle portion of the second planarization layer.

For an implementation, the first internal mirror is formed at circumferences of the first slit. The second internal mirror is formed at circumferences of the second slit.

For an implementation, the anode electrode is formed except the first slit and the second slit.

For an implementation, the first slit and the second slit are depressed down from an upper surface of the second planarization layer to an upper surface of the first planarization layer.

The various implementations described above can be combined to provide further implementations. These and other changes can be made to the implementations in light of the above-detailed description. In general, in the following claims, the terms used should not be construed to limit the claims to the specific implementations disclosed in the specification and the claims, but should be construed to include all possible implementations along with the full scope of equivalents to which such claims are entitled. Accordingly, the claims are not limited by the disclosure.

What is claimed is:

1. A light emitting display device comprising:
a substrate;
a plurality of pixels arranged on the substrate, each of the pixels having an emission area and a non-emission area;
a light emitting diode disposed within the each pixel;
a side mirror disposed at an outer circumference of the light emitting diode; and
a first internal mirror and a second internal mirror that are disposed inside the light emitting diode and that have arc shapes that curve toward each other in a plan view;
wherein one end point of the second internal mirror, one end point of the first internal mirror, and a center point of the light emitting diode are colinear in the plan view.

2. The light emitting display device according to claim 1, wherein the first internal mirror and the second internal mirror are disposed on opposite sides of a centerline passing through the center point of the light emitting diode in the plan view, and
wherein the light emitting display device further includes a third internal mirror having a linear segment shape arranged along the centerline.

3. The light emitting display device according to claim 2, further including: a fourth internal mirror having a linear segment shape passing the center point of the light emitting diode and perpendicular to the centerline.

4. The light emitting display device according to claim 1, wherein the first internal mirror and the second internal mirror are disposed on opposite sides of a centerline passing through the center point of the light emitting diode in the plan view, and
wherein the light emitting display device further includes a third internal mirror having a linear segment shape passing the center point of the light emitting diode and perpendicular to the centerline.

5. The light emitting display device according to claim 1, wherein the first internal mirror and the second internal mirror are disposed on opposite sides of a centerline passing through the center point of the light emitting diode in the plan view,
wherein the centerline extends from a first side of the light emitting diode to a second side of the light emitting diode,
wherein the first internal mirror contacts a first side mirror disposed at the first side of the light emitting diode and extends inside the light emitting diode, and
wherein the second internal mirror contacts a second side mirror disposed at the second side of the light emitting diode and extends inside the light emitting diode.

6. The light emitting display device according to claim 1, wherein the arc shapes of the first internal mirror and the second internal mirror are defined as portions of respective circles with respective center points that define arc center points of the arc shapes,
wherein an arc center point of the first internal mirror is located at a midpoint of the second internal mirror that bisects the second internal mirror into two halves, and
wherein an arc center point of the second internal mirror is located at a midpoint of the first internal mirror that bisects the first internal mirror into two halves.

7. The light emitting display device according to claim 6, wherein the arc shapes of the first internal mirror and the second internal mirror each subtends a respective central arc angle, which is an angle formed by two radii connecting the arc center point to endpoints of the arc shape,
wherein a first central arc angle of the first internal mirror and a second central arc angle of the second internal mirror are greater than or equal to 60 degrees and less than 120 degrees.

8. The light emitting display device according to claim 1, wherein the first internal mirror and the second internal mirror are disposed on opposite sides of a horizontal centerline passing through the center point of the light emitting diode in the plan view, and
wherein the first internal mirror and the second internal mirror have a vertical symmetry with respect to the horizontal centerline.

9. The light emitting display device according to claim 1, wherein the first internal mirror and the second internal mirror are disposed on opposite sides of a horizontal centerline passing through the center point of the light emitting diode in the plan view, and
wherein the first internal mirror and the second internal mirror have a bilateral symmetry with respect to a vertical line passing the center point of the light emitting diode that is perpendicular to the horizontal centerline.

10. The light emitting display device according to claim 1, wherein the first internal mirror and the second internal mirror have a point symmetry with respect to the center point of the light emitting diode.

11. The light emitting display device according to claim 1, further comprising:
a first planarization layer having a first thickness on the substrate;
a second planarization layer having a second thickness, and extruded over the first planarization layer within the emission area;
an anode electrode disposed within the emission area on the second planarization layer;
an emission layer on the anode electrode, the first planarization layer, and the second planarization layer; and
a cathode electrode on the emission layer.

12. The light emitting display device according to claim 11, further comprising:
a first slit and a second slit formed at a middle portion of the second planarization layer in the plan view.

13. The light emitting display device according to claim 12, wherein the first internal mirror is formed at a circumference of the first slit, and
wherein the second internal mirror is formed at a circumference of the second slit.

14. The light emitting display device according to claim 12, wherein the anode electrode is formed on the second planarization layer except in the first slit and the second slit.

15. The light emitting display device according to claim 12, wherein the first slit and the second slit are depressed down from an upper surface of the second planarization layer to extend down towards an upper surface of the first planarization layer.

16. A light emitting display device comprising:
a substrate;
a plurality of pixels arranged on the substrate, each of the pixels having an emission area and a non-emission area;
a light emitting diode disposed within the each pixel;
a side mirror disposed at an outer circumference of the light emitting diode; and
a first internal mirror and a second internal mirror that are disposed inside the light emitting diode and that have arc shapes that curve toward each other in a plan view;
wherein the first internal mirror and the second internal mirror are disposed to have point symmetry with respect to a center point of the light emitting diode in the plan view.

17. The light emitting display device according to claim 16, wherein the first internal mirror and the second internal mirror are disposed on opposite sides of a centerline passing through the center point of the light emitting diode in the plan view, and
wherein the light emitting display device further includes a third internal mirror having a linear segment shape arranged along the centerline.

18. The light emitting display device according to claim 17, further including a fourth internal mirror having a linear segment shape passing the center point of the light emitting diode and perpendicular to the centerline.

19. The light emitting display device according to claim 16, wherein the first internal mirror and the second internal mirror are disposed on opposite sides of a centerline passing through the center point of the light emitting diode in the plan view, and
wherein the light emitting display device further includes a third internal mirror having a linear segment shape passing the center point of the light emitting diode and perpendicular to the centerline.

20. The light emitting display device according to claim 16, wherein the first internal mirror and the second internal mirror are disposed on opposite sides of a centerline passing through the center point of the light emitting diode in the plan view,
wherein the centerline extends from a first side of the light emitting diode to a second side of the light emitting diode,
wherein the first internal mirror contacts a first side mirror disposed at the first side of the light emitting diode and extends inside the light emitting diode, and
wherein the second internal mirror contacts a second side mirror disposed at the second side of the light emitting diode and extends inside the light emitting diode.
